(19) United States
(12) Patent Application Publication
(10) Pub. No.: US 2004/0222638 A1
(43) Pub. Date: Nov. 11, 2004

(54) Apparatus and method for providing electrical energy generated from motion to an electrically powered device

(76) Inventor: Vladimir Bednyak, Vernon Hills, IL (US)

Correspondence Address: Edward Etkin, Esq., Suite 3C, 4804 Bedford Avenue, Brooklyn, NY, 11235, US

(21) Appl. No.: 10/838,110

(22) Filed: May 3, 2004

Related U.S. Application Data
(60) Provisional application No. 60/468,917, filed on May 8, 2003.

(51) Int. Cl. H02P 9/04; H01L 21/76

(52) U.S. Cl. 290/1 R

(57) ABSTRACT

An apparatus and method for providing electrical energy to one or more functional components of electrical device and/or to recharge a rechargeable power supply of the device, by deriving the electrical energy from motion of the device, is disclosed. The inventive apparatus preferably includes one or more novel oscillating weight-based kinetic electrical power generators (KEPG) that include a novel oscillating weight having an internal cavity with a freely movable acceleration element disposed therein, resulting in improved acceleration and oscillation capabilities and lower power generation motion threshold for the KEPG. The various embodiments of the present invention disclose a variety of novel electrical devices and articles (carrying cases, clothing, etc.) incorporating, or usable in conjunction with, electrical devices, that preferably and advantageously utilize one or more novel KEPGs for generating electrical energy from motion and feeding it to the devices and/or recharging the device batteries. The inventive embodiments also include a self-recharging battery incorporating one or more KEPGs to provide a continuous recharge, a KEPG-based portable recharger capable of connection to a charging port of an electrical device, a KEPG-based motion sensor, and an electrical device with a mechanical user-operable input that includes a dual mode electrical generator incorporating one or more KEPGs.

### CROSS REFERENCE TO RELATED APPLICATIONS

The present patent application claims priority from the commonly assigned U.S. provisional patent application Ser. No. 60/468,917 entitled “Apparatus and Method for Generating Electrical Energy from Motion and From Routine Activities” filed May 8, 2003.

### FIELD OF THE INVENTION

The present invention relates generally to an apparatus and method for generating electrical energy from motion, and more particularly to an apparatus and method implemented in an electrical device or article including one or more electrical devices, for generating electrical energy from at least one kinetic electrical generator and selectively: powering the electrical device(s) connected thereto, recharging one or more rechargeable batteries of the device(s), or storing the electrical energy for future use by the device(s).

### BACKGROUND OF THE INVENTION

The multitude of electrical and electronic devices in common use today, from cellular telephones to computers to lighting systems, all depend on a steady supply of electrical energy. Such a supply is not an issue when a device is connected to a constant source of electrical energy via a land electrical power line, for example through a power receptacle. However, portable electrical devices or devices located in areas without electrical power lines (for example marine craft, space vehicles, non-powered air vehicles, etc.), must acquire their electrical energy from batteries or through other electrical energy sources (solar panels, hydro-power generators, fuel cells, wind-power generators, etc.). Examples of portable electrical devices include, but are not limited to: miniature electrical devices (such as: an implantable cardiac device (pacemaker, defibrillator), a chronograph, a miniature surveillance device (remote mini-camera, concealable tracking device, motion detecting device), an electronic tag (RF, etc.), and small to medium electrical devices (such as a personal electronic device (a mobile telephone, a radio, a television, a personal digital assistant (PDA), a media player and/or recorder, a video or photo camera, a game console, binoculars, night vision goggles, a portable computer (notebook, laptop, or tablet computer), a portable data acquisition device (i.e. RF or barcode scanner), a portable medical diagnostic or treatment delivery device (e.g. blood pressure monitor, electrocardiogram machine, defibrillator, drug pump, etc.), a surveillance device (remote camera, tracking device, motion detecting device), a weapon or weapon accessory with electrical or electronic capabilities (e.g., a camera and/or scope on a rifle, a taser, a laser targeting sight, or a laser targeter), toys, and robotic devices.

In the past several decades, the proliferation of portable electrically powered devices, such as illustrated above, has created a great need for efficient and miniaturized sources of electrical energy. Utilization of ordinary disposable batteries (alkaline, etc.) greatly increases the cost of operation of such devices, especially because many electrical devices (for example, digital cameras) draw electrical energy in such a way as to quickly exhaust a conventional battery. In addition, users find frequent replacement of batteries and carrying spare batteries very inconvenient.

Therefore, in recent years, rechargeable batteries (such as Metal Oxide, NiCad, etc.) are typically used. Nevertheless, while rechargeable batteries, especially the latest currently available models, offer longer operational time and lower cost of operation, they are still finite sources of electrical energy and must be recharged relatively often. This is problematic for high utilization devices, such as PDAs, media recorders/players, portable telephones and laptop computers. Furthermore, because recharging involves connecting the device or its battery to a land power line, the recharging process limits the user's mobility. For that reason, many users are forced to carry one or more additional spare rechargeable batteries for their devices, and in some cases a recharging device or adapter (for example, when traveling). Other portable electrical devices, such as flashlights and the like, can also benefit from efficient long-lasting sources of electrical energy and sometimes rely on rechargeable batteries to lower operational costs with similar disadvantages as previously described electrical devices.

In some cases, where the use of rechargeable batteries is not practical or possible (such as in pacemakers and wrist chronographs), special extended duration non-rechargeable batteries (for example, lithium batteries) are used. While such batteries may be replaceable, in the case of implantable medical devices, surgical intervention is necessary to extract the device. Furthermore, to maintain sterility, batteries in implantable medical devices are never changed, even when the device is extracted. Rather, the implantable device is disposed of, and replaced with a new one.

In addition, certain critical function devices, such as medical devices (e.g. pacemakers, drug pumps, etc.), environmental hazard (chemical, radiation, and/or biological) suits, or space vehicles (satellites, space shuttle, planetary robotic vehicles, extra-vehicular activity (EVA) suits, etc.) often require very reliable and sometimes redundant sources of electrical energy.

All types of batteries (rechargeable and otherwise), suffer from two additional disadvantages. First, most batteries utilize non-recyclable toxic and/or environmentally polluting materials in their construction, making disposal of used batteries a environmental danger. Second, all batteries generate heat during operation, requiring cooling in sensitive electronic equipment (such as in portable computers). The heat generation from batteries is a particular danger in military devices where the heat signature exposes the carrier of the device to enemy infrared or other heat sensing surveillance or targeting equipment. This is particularly true of fuel cell batteries often used in military applications due to their inherent high capacity. For example, fuel cell batteries have operating temperatures that often exceed 100 degrees Fahrenheit.

To address these challenges, there has been some development in the field of portable generation of electrical energy that may be utilized to power an electrical device, to recharge the rechargeable batteries in a device, or both. Typically, previously known portable electrical generators involve some form of transduction of mechanical energy into electrical energy by implementation of the Faraday's Principle of Induction, in which motion of the generator (such as shaking or vibration) is translated into rotational movement of a coil and a magnetic rotor, at least partially disposed within the coil, relative to one another. This relative motion generates electrical energy at the coil caused by the rotation of the magnetic field of the rotor. The generated electrical energy is then typically rectified by a capacitor circuit to convert it to direct current (DC) power. The electrical energy may be used directly, stored, or routed to a rechargeable battery.

Some previously known kinetic-power generation (hereinafter “KEPG”) systems are configured to derive electrical energy from relative linear motion of the coil and rotor—these systems require vigorous shaking motion to generate electrical energy and offer some advantages in that the desired electrical energy is relatively quickly generated. However, this approach requires direct dedicated action by the user to generate the energy that is difficult and impractical to sustain. Also, only small amounts of electrical energy may be practically generated in this manner. Furthermore, vigorous motion of certain electronic devices, such as laptop computers or medical devices, is highly undesirable.

In many previously known KEPG systems, an attempt has been made to utilize ordinary motion (such as walking, moving a limb, floating on waves in the water, etc.) to generate electrical energy in a manner that is transparent to the user. In most of these systems, translation of ordinary motion has been accomplished by utilizing an oscillating weight to convert relatively linear motion of the KEPG system into rotary motion of the rotor relative to the coil via a mechanical motion converter, such as a gear train. However, except for limited use in wrist chronographs, these systems have failed to achieve commercial success for a number of reasons. First, miniaturized KEPG systems must overcome a significant challenge in that the oscillating weight responsible for translating vibrational or semi-linear motion into desirable rotary motion must be of a very small size which makes it light, and thus limits its acceleration and range of angular motion during continuous operation, resulting in a decrease overall system performance proportional to the oscillating weight's size. Accordingly, previously known KEPG systems cannot provide sufficient amounts of electrical energy for tiny, small or medium electrical devices to justify their use.

In addition, due to the construction and operational characteristics of the previously known oscillating weights, the motion threshold—i.e. the minimum mechanical disturbance (in terms of the magnitude and directionality of inertial forces) that must be applied to the electrical device and transferred to the oscillating weight, to cause the weight to achieve sufficient repetitive angular motion to cause rotation of the rotor—is typically very high. Thus, to exceed the motion threshold, a device equipped with a previously known KEPG system must be subjected to significant mechanical disturbances to derive a meaningful benefit from the KEPG system. This is one of the reasons why the only commercially successful use of oscillating weight-based KEPG systems has been in wrist chronographs—the routine motion of an average person's wrist during typical daily activities continually provides a sufficient amount of mechanical disturbances of a magnitude that meets or exceeds a typical wrist chronograph-based KEPG system's motion threshold.

The challenge of the high motion threshold in previously known KEPG systems have also stymied their utilization in applications where the size of a KEPG system is less of an issue—for example, in marine power (buoy, marine craft, etc.) applications. In marine applications, moderately calm to slightly choppy waters—the most common marine conditions in the majority of the bodies of water, will typically fail to produce sufficient mechanical disturbances to the marine device or craft to exceed the motion threshold of most KEPG systems.

Fortunately, a co-pending, commonly assigned U.S. patent application entitled “APPARATUS AND METHOD FOR GENERATING ELECTRICAL ENERGY FROM MOTION” of V. Bednyak (hereinafter: “Bednyak patent application”), which is hereby incorporated herein by reference in its entirety, provides an advantageous solution to the above-described problems and challenges, and also successfully overcomes the drawbacks of the previously known KEPGs, by providing a novel KEPG utilizing a novel oscillating weight with improved acceleration and performance capabilities, resulting in a significantly lower motion threshold than any previously known KEPG, even when the oscillating weight is of relatively small size. Moreover, the novel oscillating weight may be readily utilized, or adapted for use, in most conventional KEPGs to take advantage of other innovations in particular KEPGs, such as, for example, improved motion conversion assemblies or gear trains, and electrical energy processing and/or storage circuitry. Various embodiments of the novel KEPG, including one utilizing multiple oscillating weights, as well as a KEPG system with electrically coupled KEPG sub-systems, are shown and described therein.

Nevertheless, because KEPGs have not been generally utilized in conventional electrical devices, or in articles or structures incorporating electrical devices (with some exceptions, such as flashlights and wrist chronographs), a challenge remains to discover the optimal ways in which the novel KEPG of the above-incorporated patent application, or other possible future KEPGs with equivalent or superior characteristics, may be utilized to provide electrical energy directly to the electrical devices, and/or to recharge the electrical devices, and/or to store electrical energy for future use by the devices.

Thus, it would be desirable to provide a wider variety of improved and advantageous applications for one or more superior KEPG systems with minimized motion thresholds and improved efficiency, to provide, in response to motion thereof, electrical energy directly to electrical devices, and/or to recharge the electrical devices, and/or to store electrical energy for future use by the devices.

### BRIEF DESCRIPTION OF THE DRAWINGS

In the drawings, wherein like reference characters denote corresponding or similar elements throughout the various figures:

FIG. 1 is a schematic block diagram of an exemplary embodiment of an inventive electrical device incorporating one or more functional components, and a novel kinetic power generating system (hereinafter, KEPG system), for generating, storing, and/or delivering electrical energy to one or more functional components of the device;

FIG. 2 is a schematic block diagram of an exemplary embodiment of an inventive electrical device having one or more functional components and a rechargeable battery system, and incorporating multiple novel KEPG sub-systems, for selectively generating, storing, and/or delivering electrical energy to one or more functional components of the device, and/or for selectively recharging the rechargeable battery system;

FIG. 3 is a schematic block diagram of an exemplary embodiment of an inventive electrical device having multiple functional components, a rechargeable battery system, and incorporating multiple novel KEPG sub-systems, for selectively generating, storing, and/or delivering electrical energy, where the electrical energy is delivered from one or more of the KEPG sub-systems to one or more functional components, and where one or more of the KEPG sub-systems is selectively utilized for recharging the rechargeable battery system;

FIG. 4 is a schematic block diagram of an exemplary embodiment of an inventive self-recharging rechargeable battery for use with an electrical device, having a battery recharging component, and incorporating one or more novel KEPG sub-systems, for selectively generating, storing, and/or delivering electrical energy to the battery recharging component;

FIG. 5 is a schematic block diagram of an exemplary embodiment of an inventive portable recharge system for recharging rechargeable batteries in a portable electrical device, the portable recharge system having a recharging component, and incorporating one or more novel KEPG sub-systems connected thereto, for selectively generating, storing, and/or delivering electrical energy to the batteries in the portable electrical device through an external connector;

FIG. 6 is a schematic block diagram of an exemplary first embodiment of an inventive portable electrical device carrying appliance, configured as a cradle, incorporating a recharge system for recharging rechargeable batteries in the portable electrical device placed in the cradle, the recharge system having a recharging component, and incorporating one or more novel KEPG sub-systems connected thereto, for selectively generating, storing, and/or delivering electrical energy to the batteries in the portable electrical device through a connector in the cradle;

FIG. 7 is a schematic block diagram of an exemplary second embodiment of an inventive portable electrical device carrying appliance, configured as a case, incorporating a recharge system for recharging rechargeable batteries in the portable electrical device placed in the case, the recharge system having a recharging component, and incorporating one or more novel novel KEPG sub-systems connected thereto, for selectively generating, storing, and/or delivering electrical energy to the batteries in the portable electrical device through a connector in the case;

FIG. 8A is a schematic block diagram of an exemplary first embodiment of an inventive clothing or wearable gear article, having one or more integrated electrical device and having a power output port for powering additional electrical devices connected thereto, the clothing or wearable gear article incorporating one or more novel KEPG sub-systems, connected to the multiple integrated electrical devices and to the power output ports, for selectively generating, storing, and/or delivering electrical energy thereto;

FIG. 8B is a schematic block diagram of an exemplary second embodiment of the inventive clothing or wearable gear article, having one or more integrated electrical device and a having power output port for powering additional electrical devices connected thereto, the clothing or wearable gear article incorporating one or more novel KEPG sub-systems connected to the multiple integrated electrical devices and to the power output ports, for selectively generating, storing, and/or delivering electrical energy thereto;

FIG. 9 is a schematic block diagram of an exemplary embodiment of a marine floating structure having one or more functional components and an optional rechargeable battery system, and incorporating one or more novel KEPG sub-systems, for selectively generating, storing, and/or delivering electrical energy, where the electrical energy is delivered from one or more of the KEPG sub-systems to one or more functional components, and where one or more KEPG sub-systems is selectively utilized for recharging the optional rechargeable battery system;

FIG. 10 is a schematic block diagram of an exemplary embodiment of a watercraft having one or more functional components or a power output port for powering an electrical device connected thereto, an optional rechargeable battery system, and incorporating one or more novel KEPG sub-systems, for selectively generating, storing, and/or delivering electrical energy, where the electrical energy is delivered from one or more of the KEPG sub-systems to one or more functional components, or to the power output port, and where one or more of the KEPG sub-systems is selectively utilized for recharging the optional rechargeable battery system;

FIG. 11 is a schematic block diagram of an exemplary embodiment of a motion sensor, utilizing a KEPG system to generate an indicator signal responsive to a mechanical disturbance applied to the sensor;

FIG. 12 is a schematic block diagram of an exemplary embodiment of an inventive electrical device having at least one user-operable operable mechanical input element, one or more functional components, and a rechargeable battery system, and a dual mode electrical generator incorporating one or more novel KEPG sub-systems and a mechanical converter system, for selectively generating, storing, and/or delivering electrical energy to one or more functional component of the device and/or for selectively recharging the rechargeable battery system, in response both to motion of the device, and also to operation of the mechanical input element by the user;

FIG. 13A is a schematic block diagram of a first exemplary embodiment of the dual mode electrical generator used in the electrical device of FIG. 12, in which a single mechanical converter system, which applies mechanical disturbances to one or more KEPG sub-systems, is responsive one or more user-operable mechanical input elements;

FIG. 13B is a schematic block diagram of a second exemplary embodiment of the dual mode electrical generator used in the electrical device of FIG. 12, in which multiple mechanical converter systems, which apply mechanical disturbances to one or more KEPG sub-systems, are each responsive to one or more user-operable mechanical input elements;

FIG. 14 is a schematic block diagram of an exemplary first embodiment of the novel KPEG system, for generating, delivering, and/or storing electrical energy, the novel KEPG system utilizing a novel oscillating weight with improved acceleration characteristics, and having a minimized motion threshold; and

FIG. 15 is a schematic block diagram of an exemplary second embodiment of the novel KEPG system, utilizing multiple coupled KEPG sub-systems for generating, delivering, and/or storing electrical energy.

### SUMMARY OF THE INVENTION

The various embodiments of the present invention advantageously overcome the drawbacks and disadvantages of previously known portable and/or remote electrically powered devices, by utilizing inventive power supply systems based on kinetic electrical power generators (hereinafter “KEPGs”) that generate electrical energy from motion thereof, to provide the devices with electrical energy, and/or to recharge a rechargeable an additional device power supply, and/or to store generated electrical energy for future use.

Preferably, the KEPGs used in accordance with the inventive embodiments, are oscillating weight-based and are substantially similar to one or more of the inventive KEPG embodiments disclosed in the above-incorporated Bednyak patent application. In summary, the KEPG provided in the Bednyak patent application, utilizes a novel oscillating weight with improved acceleration and performance capabilities, resulting in a significantly lower motion threshold than any previously known KEPG, even when the oscillating weight is of relatively small size. The Bednyak KEPG may also include an optional transparent or open area to enabling a view of operation of the oscillating weight for decorative purposes. Of course other novel KEPGs with similar or superior characteristics may be readily utilized in accordance with the present invention.

The present invention provides a number of exemplary embodiments for a wide variety of electrical devices, electrical device accessories, and articles and/or structures incorporating one or more electrical devices, that advantageously utilize one or more novel KEPG systems to provide, in response to motion, electrical energy to functional components thereof, in addition to, or instead of, other power supply systems (e.g., batteries, etc.). If the other energy sources are rechargeable, the KEPG system(s) continuously recharge the energy sources. In accordance with the present invention, exemplary embodiments of such electrical devices, electrical device accessories, and articles and/or structures incorporating one or more electrical devices, include:

A novel electrical device with one or more functional components, a KEPG connected to at least one functional component, and an optional rechargeable power supply (e.g., battery) system. The KEPG may provide electrical energy generated from motion of the device directly to the connected functional component(s), to the rechargeable battery system to recharge the batteries thereof, or to both the functional component(s) and the battery system;

A novel electrical device with one or more functional components, and multiple KEPGs that are connected to an electrical energy aggregating unit that is connected to the functional component(s), optional one or more independent KEPGs, an optional secondary power supply connected to the same or to different functional component(s) as the electrical energy aggregating unit, and an optional rechargeable battery system. The optional independent KEPGs and the aggregating unit may provide electrical energy, generated by the various KEPGs from motion of the device, directly to the connected functional component(s), to the rechargeable battery system to recharge the batteries thereof, or to both the functional component(s) and the battery system;

A novel self-recharging rechargeable battery for use with an electrical device, incorporating one or more novel KEPG systems, for generating electrical energy from the motion of the battery (mounted within a device or otherwise), and for selectively delivering electrical energy to the battery recharging component to continuously recharge the battery;

A novel portable recharge system for recharging rechargeable batteries in a portable electrical device, the portable recharge system including a recharging component, and incorporating one or more novel KEPG systems connected thereto, for generating electrical energy from the motion of the recharge system, and for delivering electrical energy to the rechargeable batteries in the portable electrical device through an external connector, to charge the batteries when the electrical device is connected to the novel recharge system and the recharge system is in motion;

An inventive portable electrical device carrying case or cradle incorporating one or more recharge systems for recharging rechargeable batteries in a portable electrical device placed in the case or cradle, each recharge system having a recharging component, and incorporating one or more novel KEPG systems connected thereto, for generating electrical energy, and a connector for delivering the energy to the batteries in the portable electrical device, when the electrical device is placed into the case or cradle,

An inventive clothing or wearable gear article, having one or more integrated electrical devices and optionally having one or more power output ports for powering additional electrical devices connected thereto, the clothing or wearable gear article incorporating one or more novel KEPG systems connected to the one or more integrated electrical devices and to the optional power output ports, for selectively generating, and/or delivering electrical energy thereto, and for storing electrical energy for future use;

A marine floating structure, having one or more functional components and an optional rechargeable battery system, and incorporating one or more novel KEPG systems, for selectively generating, storing, and/or delivering electrical energy, where the electrical energy is delivered from one or more of the KEPG systems to one or more functional components, and where one or more KEPG systems may be selectively utilized for recharging the optional rechargeable battery system;

A watercraft having one or more functional components and/or a power output port for powering an electrical device connected thereto, an optional rechargeable battery system, and incorporating one or more novel KEPG systems, for selectively generating, storing, and/or delivering electrical energy, % where the electrical energy is delivered from one or more of the KEPG systems to one or more functional components, or to the optional power output port, and where one or more of the KEPG systems may be selectively utilized for recharging the optional rechargeable battery system;

A motion sensor, utilizing a KEPG to generate a signal responsive to a mechanical disturbance applied to the sensor, having an indicator unit for indicating the presence (and, optionally, the severity) of the mechanical disturbance in response to the signal, as well as an optional communication unit to transmit the indicator data to a remote location; and

An inventive electrical device having at least one user-operable operable mechanical input element (for example a keyboard, keypad, or individual buttons), one or more functional components, a rechargeable battery system, and a dual mode electrical generator incorporating one or more novel KEPG systems and a mechanical converter system that applies a mechanical disturbance to one or more KEPG systems when one or more of the mechanical input elements are activated, for selectively generating, storing, and/or delivering electrical energy, to one or more functional components of the device, and/or for selectively recharging the rechargeable battery system, in response both to motion of the device, and also to operation of the mechanical input element by the user.

Other objects and features of the present invention will become apparent from the following detailed description considered in conjunction with the accompanying drawings. It is to be understood, however, that the drawings are designed solely for purposes of illustration and not as a definition of the limits of the invention, for which reference should be made to the appended claims.

### DESCRIPTION OF THE PREFERRED EMBODIMENTS

The various embodiments of the present invention relate to a wide variety of electrical devices, accessories for electrical devices, and articles, structures and/or vehicles incorporating electrical devices and/or having interfaces capable of connecting to electrical devices, that include a novel power supply apparatus and method for efficiently generating electrical energy from motion thereof (including, but not limited to, semi-linear motion, vibration, multidirectional motion, oscillating motion, and any other type of mechanical disturbance), regardless of the size of the novel apparatus. Preferably, the embodiments of the present invention utilize one or more novel oscillating weight-based kinetic electrical power generators (hereinafter “KEPG”), with minimal motion thresholds and high efficiency, such as the KEPGs disclosed in the above-incorporated Bednyak patent application.

Before describing the present invention in greater detail, it would be useful to discuss the reasons for failure of previously known kinetic oscillating weight-based power generation devices to achieve a meaningful commercial success, and the reasons why the embodiments of the present invention have not been heretofore possible or practical.

There are two key challenges for any kinetic electrical power generator (hereinafter “KEPG”) that relies on an oscillating weight to provide the reciprocating radial motion, in response to a mechanical disturbance exerted on the KEPG, that is later converted into desirable rotational motion used by the KEPG's transducer (e.g. a coil and magnetic rotor assembly) to generate electrical energy.

The first challenge, is the direct relationship of the size (and therefore mass and weight) of the oscillating weight to its efficiency, and thus to the efficiency of the KEPG system. In most portable electrical devices, available space is a great premium. Accordingly, the size of the oscillating weight must be significantly restricted, decreasing the weight's ability to gather and maintain momentum resulting in a lowered likelihood of the weight producing meaningful oscillating motion, and thus causing a corresponding significant decrease in KEPG efficiency. Typically, this efficiency decrease is sufficient to make utilization of a conventional KEPG impractical.

The second, and even more important challenge, is the magnitude of a motion threshold for a conventional KEPG's oscillating weight. Due to the construction and operational characteristics of a typical previously known oscillating weight, the motion threshold—i.e. the minimum mechanical disturbance (in terms of the magnitude and directionality of inertial forces) that must be applied to the electrical device and transferred to the oscillating weight, to cause the weight to achieve sufficient repetitive angular motion to cause rotation of the rotor—is typically very high. Thus, to exceed the motion threshold, a device equipped with a previously known KEPG system must be subjected to significant mechanical disturbances to derive a meaningful benefit from the KEPG system. This is one of the reasons why the only commercially successful use of oscillating weight-based KEPG systems has been in wrist chronographs—the routine motion of an average person's wrist during typical daily activities continually provides a sufficient amount of mechanical disturbances of a magnitude that meets or exceeds a typical wrist chronograph-based KEPG system's motion threshold.

The inability of previously known KEPGs to overcome these challenges resulted in the KEPGs only being commercially utilized in extremely limited niche applications, such as wrist chronographs. Attempts to utilize existing KEPGs in more demanding electrical devices (i.e. in virtually any electrical device other than a wrist chronograph) have met with failure.

The embodiments of the present invention successfully overcome both of the above challenges by providing a novel framework utilizing one or more high efficiency/low motion threshold KEPG(s) (preferably utilizing a novel oscillating weight with improved acceleration and performance capabilities) in a wide variety of useful configurations.

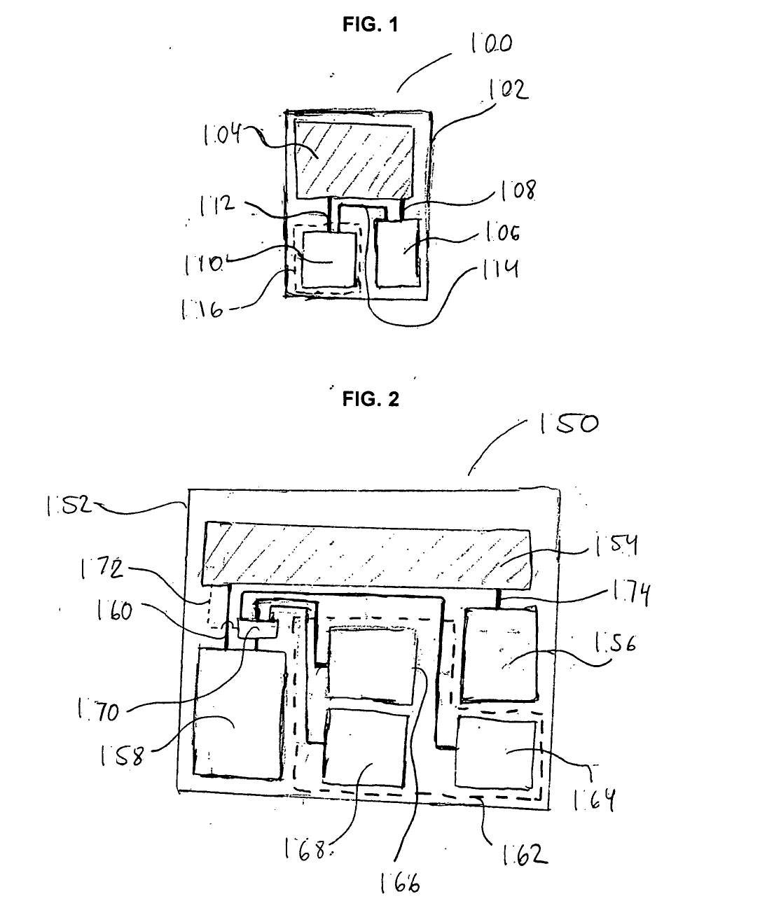

It should be noted that, aside from the novel KEPG systems and the inventive arrangement and configuration thereof, other components that may be utilized in the inventive embodiments, are generally well known in the art. Thus, there is no need to provide detailed descriptions or drawings of such device components as rechargeable power supplies (e.g., rechargeable batteries), power output ports, or recharge control units. Accordingly, in the various embodiments of the present invention, shown and described below in conjunction with FIGS. 1-13B all non-inventive components are described in a general manner and in terms of their desired functionality. One skilled in the art can readily select such existing components for use in the inventive embodiments as a matter of design choice or convenience, without departing from the spirit of the present invention.

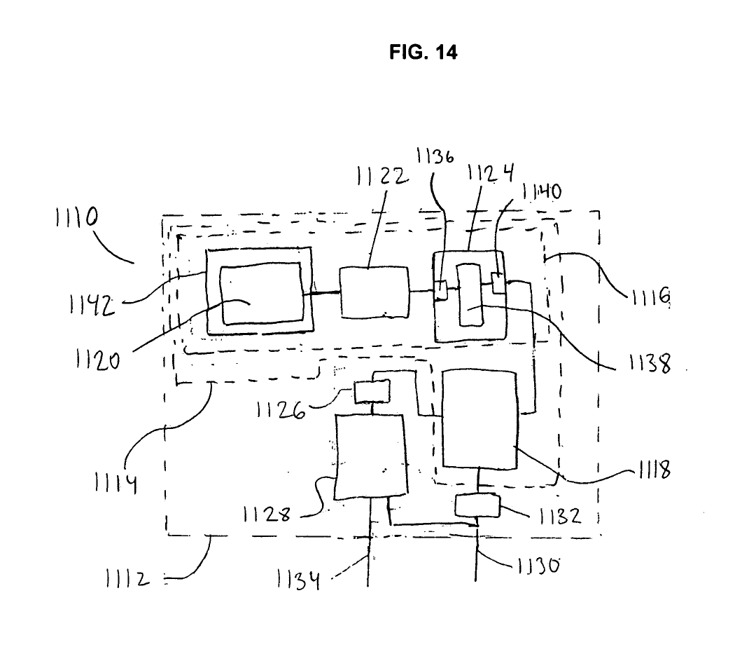

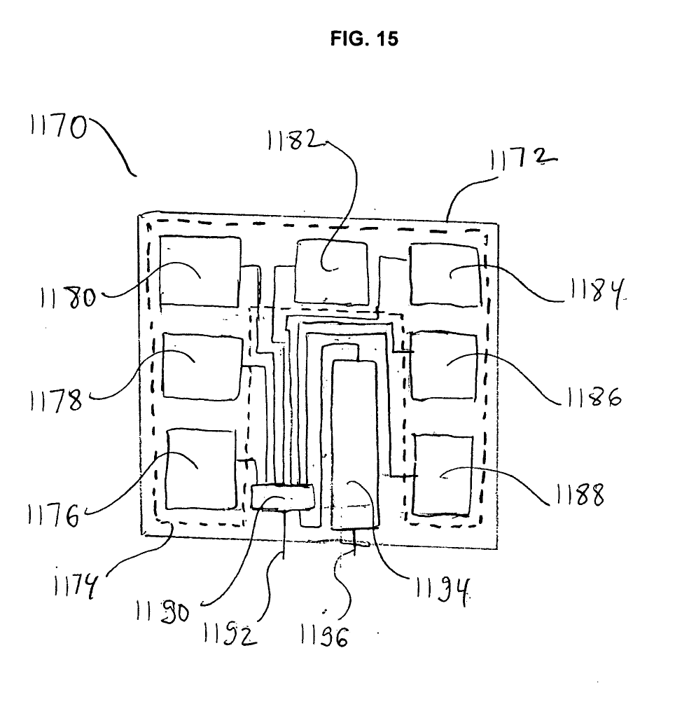

It should also be noted that the FIGS. 1-13B, of the drawings, showing the various embodiments of the present invention, as well as FIGS. 14, 15, are presented as schematic diagrams to describe and show the functional elements and components of the inventive embodiments and their interconnections, and are not meant to show or describe the actual or preferred positions of such elements or components, or of sizes or shapes of the components, unless specifically noted otherwise in the description of a figure. Accordingly, as a matter of design choice, and without departing from the spirit of the invention, one skilled in the art can readily select, configure, and position the various elements and components of any embodiment of the present invention, as long as the inventive functional requirements and interconnections, as well as any limitations on components or positions thereof provided in conjunction with the descriptions of the embodiments, are adhered to.

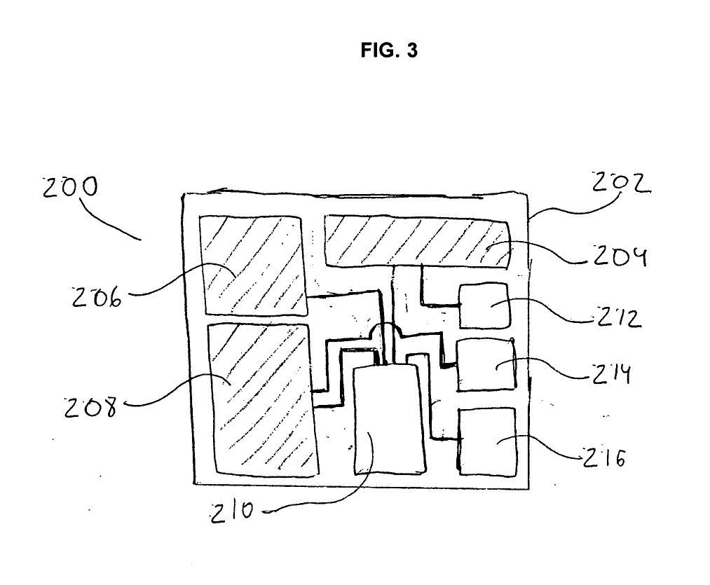

The KEPGs that are preferred for utilization in conjunction with the inventive embodiments of FIGS. 1-13B, are shown and described, by way of example, in conjunction with FIGS. 14, and 15, below (corresponding to FIGS. 1 and 3 of the above-incorporated Bednyak patent) as KEPG 1110 (a single kinetic generator) and KEPG 1170 (a generator utilizing multiple electrically coupled KEPGs 10), respectively. In essence, KEPGs 1110, 1170, both utilize a novel oscillating weight that achieves its superior and advantageous characteristics through an interior hollow cavity with a freely mobile acceleration element disposed therein. When the KEPG 1110, 1170 are subjected to motion, the movement of the acceleration element within the cavity of the novel oscillating weight greatly increases the likelihood, the duration, the acceleration, and the angular range of motion of the oscillating weight, resulting in a greater response to the motion of the KEPGs 1110 and 1170, and thus lowering the motion threshold as well as increasing the overall efficiency thereof. Because of the action of the acceleration element, the novel oscillating weight provides a performance that is vastly superior to conventional weights that are of significantly greater size, and thus enables advantageous utilization of the novel KEPGs 1110 and 1170 in applications that were previously impractical.

Referring now to FIG. 1, an exemplary embodiment of an inventive electrical device, incorporating the novel KEPG 1110 and/or KEPG 1170, is shown as an electrical device 100. The electrical device 100 may be any electrical device of any size that performs one or more functions and that requires electrical energy for operation. Thus, the electrical device 100 may be a miniature device, such as a pacemaker, a small device, such as a digital camera, a medium device, such as a notebook computer, or a large device such as a portable medical diagnostic unit.

The electrical device 100 includes a housing 102, a functional component 104 (which optionally may include two or more functional sub-components) for performing the intended functions of the device 100, a KEPG 110 for providing electrical energy to the functional component 104 in response to motion of the device 100 through a power link 112, and an optional power supply 106 for providing electrical energy to the functional component 104 under predefined conditions, for example, when the device 100 is immobile. If the power supply 106 is rechargeable, an optional recharge link 114 may be provided to electrically connect the KEPG 110 to the power supply 106, so that the KEPG 110 may selectively recharge the power supply 106.

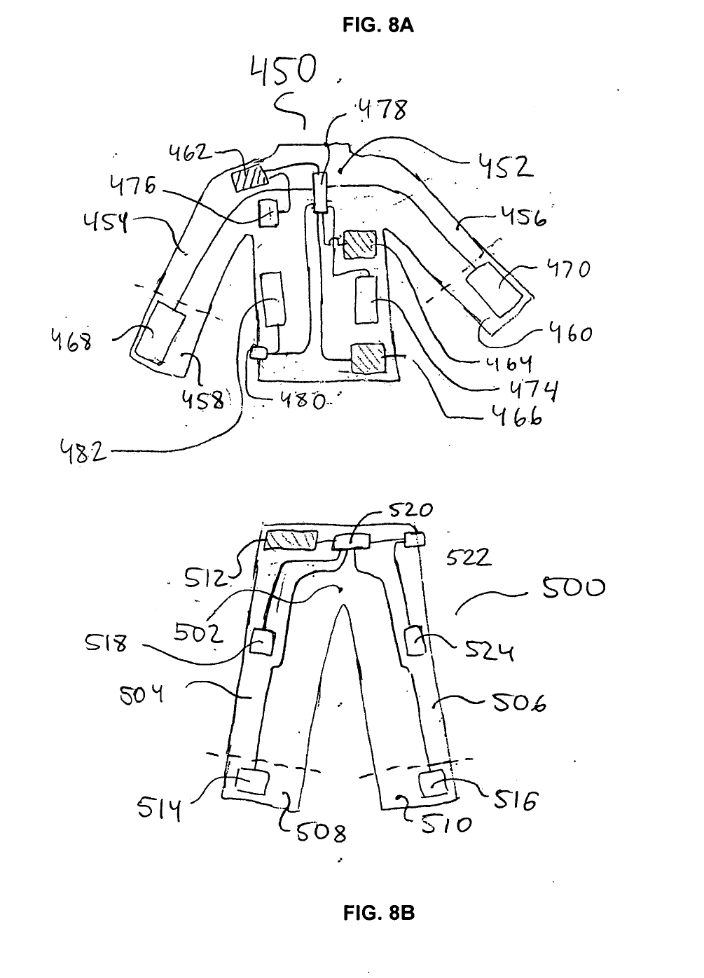

The housing 102, may be any casing sized, shaped and constructed in accordance with the specific type of the device 100, and may be composed of any suitable material or group of materials. If the KEPG 110 is provided with a viewing area (such as the viewing area 1142 of FIG. 14) for viewing the oscillating weight of the KEPG 110 (for example, if the weight includes one or more decorative features in accordance with FIGS. 8-11 of the above-incorporated Bednyak patent application), the housing 102, may also include an optional viewing window 116 on its surface, and aligned with the viewing area of the KEPG 110 to enable the user of the device 100 to view the KEPG 110 in operation.

The functional component 104, is essentially any component or group of components other than a power supply, than performs the intended function of the device 100. For example, if the device 100 is a basic mobile telephone, the functional component 100 would include at least the following sub-components: the keypad and other buttons, the microprocessors and related elements, the memory, the headphone port, the screen, the speaker and microphones, and the antenna and related elements. The KEPG 110 is preferably the KEPG 1110 (FIG. 14) if the device 100 is miniature, and a KEPG 1110 or the KEPG 1170 (FIG. 15) if the device 100 is small or larger. The power supply 106 may be any conventional power storage supply, such as a battery or a capacitor device, and is preferably rechargeable. Alternately, if the power supply 106 is not rechargeable, it may be any form of a generator, such as a solar-based generator, a wind-based generator, or a hydro-based device. These generators typically require additional components to collect the energy that is converted into electrical energy (e.g., a solar panel for the solar-based generator, etc.).

The utilization of the electrical energy provided by the KEPG 110 may be determined as a matter of design choice, without departing from the spirit of the invention. A specific utilization arrangement may be pre-determined for the device 100, or optionally, a specific arrangement may be selected by a sub-component of the functional component 104, such as a power management unit (not shown). In accordance with the present invention, at least the following novel KEPG 110 utilization arrangements are contemplated:

The KEPG 110 continually provides electrical energy, generated from motion of the device 100, directly to the functional component 102 through the power link 112;

When the device 100 utilizes the power supply 106 as a primary source of electrical energy, the KEPG 110 accumulates and stores electrical energy, generated from motion of the device 100, and is only fed to the functional component 102 through the power link 112, when the power supply 106 is depleted or fails;

When the device 100 utilizes the power supply 106 as a primary source of electrical energy, and the power supply 106 is rechargeable, the KEPG 110 continually provides electrical energy, generated from motion of the device 100, to the power supply 106 through the recharge link 114, to recharge the power supply 106. When the power supply 106 is at full capacity, the KEPG 110, optionally accumulates and stores electrical energy, generated from motion of the device 100, and only feeds it to the power supply 106, when it becomes depleted; and

The KEPG 110 continually provides a first portion of electrical energy, generated from motion of the device 100, directly to at least a portion of the functional component 102 through the power link 112, and, when the power supply 106 is rechargeable, the KEPG 110 continually provides a second portion of electrical energy, generated from motion of the device, 100, to the power supply 106 through the recharge link 114, to recharge the power supply 106. When the power supply 106 is at full capacity, the KEPG 110, optionally accumulates and stores electrical energy, generated from motion of the device 100, and only feeds it to the power supply 106, when it becomes depleted.

Referring now to FIG. 2, an exemplary embodiment of an inventive electrical device having a rechargeable battery system, and incorporating multiple novel KEPGs 1110 and/or 1170 is shown as an electrical device 150. The electrical device 150 may be any electrical device of small size or larger that performs one or more functions and that requires electrical energy for operation. Thus, the electrical device 150 may be a small device, such as a PDA, a medium device, such as a tablet computer, or a large device such as a military portable radio. In configuration and operation with respect to KEPG utilization, the device 150 is substantially similar to the device 100 of FIG. 1, with several differences as noted below.

The electrical device 150 includes a housing 152, a functional component 154 (which optionally may include two or more functional sub-components) for performing the intended functions of the device 150, a KEPG system 162 that includes one or more KEPG (for example, KEPGs 1110 and/or 1170) sub-systems, shown as KEPG sub-systems 164-168 by way of example, for providing electrical energy to an electrical energy aggregating unit 170, in response to motion of the device 150, an optional back-up power supply 156 connected to the functional component 154 through a power link 174, and an optional rechargeable power supply 158 for providing electrical energy to the functional component 154 through a power link 160 under predefined conditions, for example, when the device 150 is immobile.

While the KEPG system 162 is shown in FIG. 2 as including three KEPG sub-systems 164-168 by way of example, it should be noted that any number of multiple KEPGs, connected to the aggregating unit 170, may be readily utilized as a matter of design choice, subject to the limitations of the size of the device 150. Each of the KEPG sub-systems of the KEPG system 162, may be equivalent to the KEPG 1110 or KEPG 70.

The aggregating unit 170 is preferably electrically connected to the power supply 158, so that the power supply 158 may be selectively recharged by electrical energy generated by the KEPG system 162 and aggregated by the aggregating unit 170. Alternately, the aggregating unit 170, may be connected directly to the functional component 154 through an optional power link 172, so that the aggregating unit 170 may provide electrical energy to the rechargeable power supply 158, to the functional component 154, or to both.

The electrical aggregating unit 170 may include any type of electrical circuitry configured for simultaneously receiving electrical energy from multiple sources and aggregating the received energy before forwarding the aggregated energy to another component or element.

The configuration of the electrical aggregation unit 170 also depends on the configuration of the KEPG sub-systems of the KEPG system 170. For example, if the KEPG sub-systems 164-168 are configured without electrical energy processing, the electrical aggregation unit 170 may include an electrical energy processing unit for processing the aggregated electrical energy received therefrom.

The housing 152, may be any casing sized, shaped and constructed in accordance with the specific type of the device 150, and may be composed of any suitable material or group of materials. Similarly to the functional component 104 (FIG. 1), the functional component 154 is essentially any component or group of components other than a power supply, than performs the intended function of the device 150. The rechargeable power supply 158 may be any rechargeable power supply, such as one or more rechargeable batteries or a capacitor device. The optional back-up power supply 156 is particularly useful in mission-critical applications (i.e. medical, military, space, etc.) to provide electrical energy to one or more sub-components of the functional component 154 in an emergency when all other power sources fail.

The back-up power supply 156 may be a conventional power supply such as a battery and/or a capacitor circuit. Optionally, the back-up power supply 156 may be a KEPG, such as the KEPG 1110 or 1170, that is supplied with the optional energy storage units 1128 or 1194, respectively, configured to address the emergency requirements of the functional component 154. The utilization of the KEPG 1110, 1170 advantageously provides a self-renewing back-up power supply 156.

Referring now to FIG. 3, an exemplary embodiment of an inventive electrical device having multiple functional components, a rechargeable power supply system, and incorporating multiple novel KEPGs 1110 and/or 1170 is shown as an electrical device 200. The various components of the electrical device 200, are substantially equivalent to the components of electrical devices 100, 150 that are described above in connection with FIGS. 1 and 2. The electrical device 200, which may be any small or larger electrical device with any desirable functionality, includes a housing 202, multiple functional components (three functional components 204-208 are shown by way of example—two or more functional components may be readily utilized), a rechargeable power supply 210 connected to all the functional components, and multiple KEPGs 212-216, some of which are connected to one or more of the functional components 204-208, while one is connected to the rechargeable power supply 210.

While only three KEPGs 212-216 are shown, it should be noted that any number of multiple KEPGs may be readily utilized as a matter of design choice subject to the limitations of the size of the device 200. It should also be noted that the connections between the various KEPGs (e.g. KEPGs 212-216), the functional components (e.g., components 204-208), and the rechargeable power supply 210, are shown by way of example to illustrate that multiple KEPGs may be utilized in complex electrical devices with multiple functional components and a rechargeable power supply, to provide electrical energy from motion of the device, to individual functional components, exclusively, or in conjunction with the power supply, and also, one or more KEPGs for providing electrical energy to recharge the power supply.

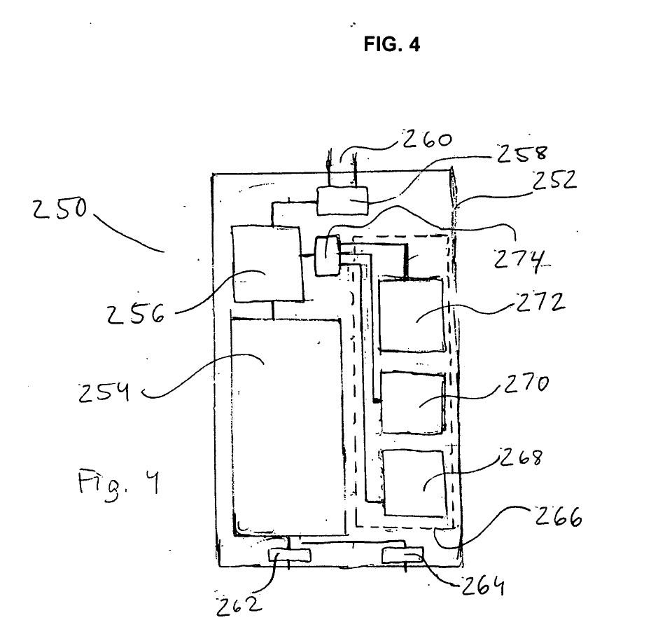

Referring now to FIG. 4, an exemplary embodiment of an inventive self-recharging rechargeable battery, incorporating one or more novel KEPGs 1110 and/or 1170, is shown as a self-charging SCR battery 250. The self-charging rechargeable battery 250 (hereinafter “SCR battery 250”), includes a housing 252, a rechargeable battery element 254 for storing electrical energy, one or more power output ports 262, 264, connected to the battery element 254 for delivering electrical energy stored therein to an external electrical device into which the SCR battery 250 is placed, a recharge control unit 256, connected to the battery element 154, for controlling application of recharging electrical energy thereto, an optional recharge port 260 for receiving electrical energy from a conventional external charger, and an optional power input interface 258, connected thereto, for delivering recharge electrical energy from the port 260 to the recharge control unit 256.

The SCR battery 250 also includes a KEPG system 266, that includes one or more KEPG (for example, KEPGs 1110 and/or 1170) sub-systems, shown by way of example as three KEPG sub-systems 268-272) connected to an electrical energy aggregating unit 274 (that is substantially similar to the aggregating unit 170 of FIG. 2). The electrical energy aggregating unit 274 is electrically connected to the recharge control unit 256. If the KEPG system 266 only includes a single KEPG sub-system, then the aggregating unit 274 is not necessary, and the KEPG system 266 may be connected directly to the recharge control unit 256.

The rechargeable battery element 254 may be any rechargeable electrical energy storage cell. The recharge control unit 256 may be any power management device for managing input power to the rechargeable battery element 254. Preferably, the recharge control unit 256 is also capable of modifying received electrical energy (for example, received from the aggregating unit 274) to match electrical parameter (voltage, current) values acceptable to the battery element 254. The power output ports 262, 264, are preferably configured to deliver electrical energy at predetermined desirable rated parameters, generally measured in volts.

The KEPG system 266, enables the SCR battery 250 to advantageously automatically recharge when the battery is subjected to motion whether on its own or when installed in an electrical device (not shown). This is particularly useful when two batteries 250 (a main and a spare) are carried by a user, because while one of the batteries powers an electrical device, the other carried battery automatically recharges. Of course, the SCR battery 250 may also be optionally recharged in a conventional manner through the port 260. Optionally, the recharge control unit 256 may include a visual indicator (not shown), visible through the housing 202, to provide information about the status of the rechargeable battery element 254 (i.e. a simple indicator of whether the element 254 is at full charge, or an indicator of the current capacity of the element 254).

The SCR battery 250 may be advantageously provided in a variety of configurations and sizes for different electrical device applications. For example, a SCR battery 250 for a PDA may be very small, may include a KEPG system 266 with only a single KEPG sub-system, and be rated at 3.5 volts, while a SCR battery 250 for a portable sonogram machine or a vehicle may include a KEPG system 266 with ten or more KEPG sub-systems and be rated at 12 volts. Thus, when properly configured, the SCR battery 250 may be readily utilized in virtually any electrical device that accepts batteries.

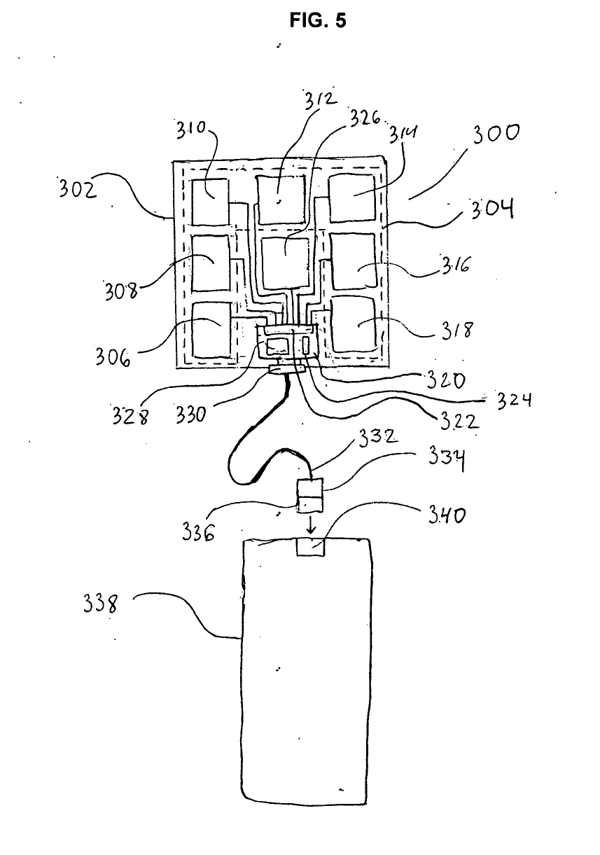

Referring now to FIG. 5, an exemplary embodiment of an inventive portable recharging system, incorporating one or more novel KEPGs 1110 and/or 1170, is shown as a recharging system 300. The primary purpose of the inventive recharging system 300 is to enable its utilization to recharge existing electrical devices having rechargeable power supplies (e.g. batteries) using electrical energy generated from motion of the recharging system 300.

The recharging system 300 includes a housing 302, a KEPG system 304, that includes one or more KEPG (for example, KEPGs 1110 and/or 1170) sub-systems, shown by way of example as seven KEPG sub-systems 306-318) for generating electrical energy from motion of the recharging system 300, a recharge control unit 320 connected to the KEPG system 304, an output power port 330 connected to the recharge control unit 320, and an output power interface 334, connected to the output power port 330 directly, or, optionally, via an elongated flexible link 332.

If the KEPG system 304 includes more than one KEPG sub-system, then the recharge control unit 320 preferably includes an electrical energy aggregating unit 322 (that is substantially similar to the aggregating unit 170 of FIG. 2) for aggregating electrical energy received from multiple KEPG subsystems. Alternately, instead of being incorporated into the recharge control unit 320, the electrical energy aggregating unit 322, may be a separate component electrically connected between the KEPG system 304 and the recharge control unit 320. Preferably, at least a portion of the KEPG sub-systems of the KEPG system 304, each include the optional energy storage units 1128 or 1194 (depending on whether the particular KEPG sub-system is a KEPG 1110 or KEPG 1170), to store the electrical energy generated from motion of the recharging system 300 for future use.

Optionally, instead of, or in addition to, the energy storage units 1128 and/or 1194 of the individual KEPG sub-systems, the recharging system 300 may include a rechargeable energy storage unit 326, which may be a rechargeable battery system, a capacitor circuit, or the like. Utilization of the rechargeable energy storage unit 326 certainly increases the energy storage capacity of the recharging system 300, at the expense of possibly increasing the size and the weight thereof. Thus, the inclusion and specific configuration of the rechargeable energy storage unit 326, is a pure matter of design choice, depending on the desired size and weight of the recharging system 300.

The recharge control unit 320 may be any power management device for modifying the electrical energy, received from the KEPG system 304, to achieve desirable values of output energy electrical parameters (voltage, current), and for managing electrical energy (e.g. selectively directing electrical energy to the rechargeable energy storage unit 326, when the recharging system 300 is generating electrical energy, but is not connected to an electrical device, directing modified electrical energy to the output power port 330 for transmission, through the link 332 and the power interface 334, to an external electrical device 338 supplied with a recharge input port 340 configured for electrical connection with the power interface 334),

The recharging system 300 may be advantageously configured for utilization in several different modes of operation, including, but not limited to:

A preconfigured mode of operation, where the recharging system 300, provides electrical energy only to a specific model or group of models of an electrical device 338, in which case:

the recharge control unit 320 is configured to modify the generated electrical energy, in accordance with predetermined electrical parameter (voltage, current) settings required by the electrical device 338 (e.g., if the device 338 is a mobile telephone, then the electrical parameter settings of the recharge control unit 320 correspond to the electrical energy parameters required by the mobile telephone model); and

The power interface 334 is configured for releasable electrical connection to the recharge input port 340 of the electrical device 338 (e.g., if the device 338 is a mobile telephone, the power interface 334 is a specific plug sized and shaped for insertion into the input port 340).

A variable mode of operation, where the recharging system 300, provides electrical energy to a variety of electrical devices 338, in which case:

the recharge control unit 320 includes a power control interface 328 accessible to a user through the housing 302, for enabling the user to change the electrical parameter modification settings of the recharge control unit 320, so that the recharging system 300 may be readily re-configured to provide electrical energy to different types or models of electrical devices 338 (e.g., to mobile phones of different manufacturers, PDAs, personal media players, etc.) and

one or more different interchangeable power interface adapters 336 are provided for releasable connection to the power interface 334, to enable connection of the recharging system 300 to a wide variety of electrical devices 338, each having different recharge input ports 340 by selecting a specific interface adapter 336 corresponding to the particular recharge input port 338.

The recharge control unit 320 may include an optional visual indicator 324, visible through the housing 302, to provide information about the status of the total electrical energy available from the system 300 (i.e. the total electrical energy stored in the energy storage units 1128 and/or 1194 of the individual KEPG sub-systems and, if utilized, in the rechargeable energy storage unit 326). The visual indicator 324 may be a simple indicator of whether the system 300 is at full charge (e.g., an LED), or a more complex indicator of the actual current capacity of the system 300. Preferably, to reduce energy drain of the system 300, the indicator 324 is selectively activated by a user wishing to receive information regarding the status of the recharging system 300.

In summary, the recharging system 300 accumulates and stores electrical energy from motion as it is carried by a user. In one application, the user may carry the recharging system 300 separately from the electrical device 338, and at some point, assuming the system 300 is subjected to enough motion to generate and store a meaningful quantity of electrical energy, connect the system 300 to the electrical device 338 to provide electrical energy thereto (i.e. to recharge the device 338).

In another application, the user may carry the recharging system 300 while connected to the electrical device 338 to continually provide electrical energy to the electrical device 338, whenever the system 300 is subjected to enough motion to generate a meaningful quantity of electrical energy.

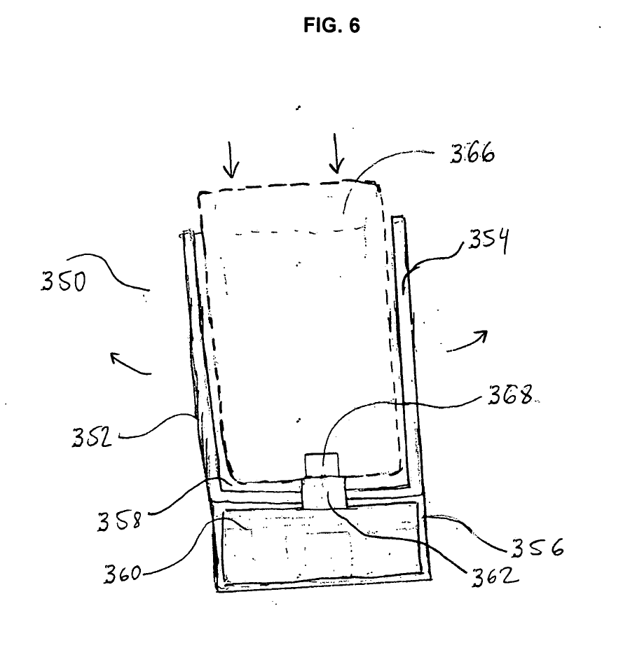

Referring now to FIG. 6, an exemplary first embodiment of an inventive portable electrical device carrying appliance with an integrated KEPG-based recharge system, is shown as a cradle 350. The cradle 350 advantageously utilizes a built-in KEPG-based recharging system to provide recharge electrical energy to rechargeable batteries in a portable electrical device placed in the cradle 350, when the cradle 350 is subjected to motion.

The cradle 350 includes a housing 352 having at least two sections: a device holding section 354 (which may be at least partially open), having an open region 358 sized and configured to receive and releasably retain an electrical device 366, having a recharge input port 368; and an enclosed power section 356 that houses a recharging system 360 and a power interface 362. The recharging system 360 is preferably substantially similar to the recharging system 300 of FIG. 5, with the power interface 334 being releasably connectable to the recharge input port 368 of the electrical device 366. An optional interface adapter 362 (corresponding to the optional power interface adapter 336 of FIG. 5) may be positioned between the output power interface (e.g., 334) of the recharge system 360 and the recharge port 368.

The optional interface adapter 362 enables the cradle 350 to be readily re-configured to provide recharge electrical energy to a variety of electrical devices 366 with different configurations of input ports 368, by replacing the interface adapter 362. The interface adapter 362 may be built in by the manufacturer of the cradle 350, or the adapter 362 may be replaceable by the user, selected from a variety of different configurations, for a specific model of the electrical device 366.

The housing 352, and various sections thereof, may be composed of one or more rigid or resilient materials as a matter of design choice or aesthetics. While the power section 356 of the housing 352 is shown, by way of example, as positioned below the holding section 354, it should be understood to one skilled in the art that the power section 356 may be positioned at the front, rear, or one of the side regions of the cradle 350, as a matter of design choice, without departing from the spirit of the invention.

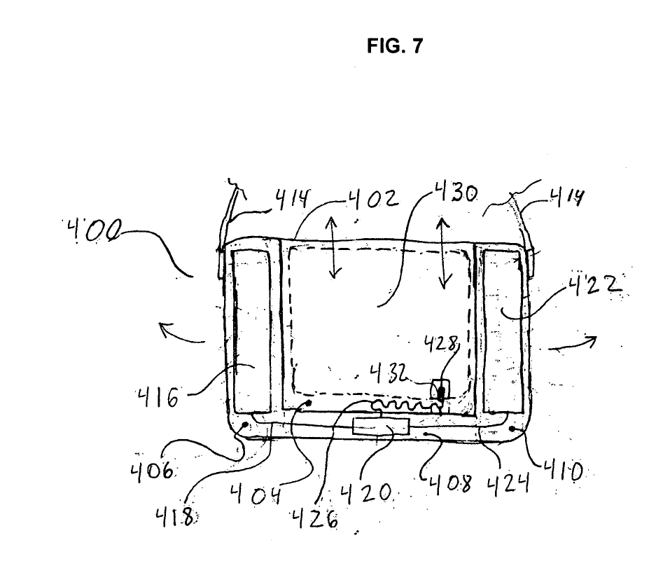

Referring now to FIG. 7, an exemplary second embodiment of the inventive portable electrical device carrying appliance with an integrated KEPG-based recharge system, is shown as a carrying case 400. The case 400 advantageously utilizes a configurable KEPG-based recharging system with one or more recharge sub-systems to provide recharge electrical energy to rechargeable batteries in a portable electrical device placed in the case 400, when the case 400 is subjected to motion.

The case 400 includes a housing 402 having a device holding section 404 sized and configured to receive and retain an electrical device 430, having a recharge input port 432; and multiple accessory sections, shown as accessory sections 406-410 by way of example, for storing items other than that the electrical device 430, for example device 430 accessories or the like, where at least one of the accessory sections 406-410 houses a recharging system, shown by way of example as two recharging systems 416, 422, positioned in accessory sections 406, and 410, respectively, for generating electrical energy from motion of the case 400. The recharging systems 416, 422 are each preferably substantially similar to the recharging system 300 of FIG. 5 and include electrical power links 418, and 424, respectively, each corresponding to the elongated flexible link 332 and output power interface 334 of FIG. 5. A strap 414 may be provided and secured to the housing 402 to enable the user to transport the case 400. Alternately, or in addition to, the strap 414, a handle (not shown) may also be provided along the top central portion of the housing 402 for the same purpose.

The case 400 also includes a power control system 420, positioned in one of the accessory sections 406-410, shown by way of example as positioned in accessory section 408, for accepting releasable electrical connections from one or more recharging systems (e.g., 416, 422) located in other accessory sections (e.g., 406, 410) via corresponding electrical power links (e.g. 418, 424), for aggregating the electrical energy received therefrom, and for selectively providing the aggregated electrical energy to the electrical device 430 to recharge the device 430 when it is placed proximal to the holding section 404. The electrical energy is delivered from the power control system 420 to the recharge input port 432 of the device 430, via a recharge link 426, supplied with a recharge interface 428 configured for connection to the port 432, that extends into the holding section 404. The length of the recharge link 426 may be selected as matter of design choice, depending on desired maximum proximity of the device 430 to the holding section 404 when the device 430 is to be connected to the link 426.

The purpose of the power control system 420, is to enable a user to releasably connect one or more recharging systems (e.g., systems 416, 422) thereto, the number of systems being limited only by the available space in the various accessory sections of the housing 402, to improve the quantity of electrical energy generated by motion of the case 400, proportionally to the number of recharging systems connected to the control system 420.

The housing 402, and various sections thereof, may be composed of one or more rigid or resilient materials as a matter of design choice or aesthetics. The quantity and positions, in the housing 402, of the accessory sections 406-410 are shown by way of example only. It should be understood to one skilled in the art that the housing 402 may include one or more accessory sections as a matter of design choice, without departing from the spirit of the invention, subject to the limitations of the desired size of the housing 402. Similarly, accessory sections (e.g., sections 406-410) may be located in different regions of the housing 402, as a matter of design choice, for example along the front or rear lengthwise side of the housing 402.

With the advent of various small and useful electronic devices (such as medical or environmental monitoring, AV recording, and wireless communication devices) building one or more such devices into clothing or wearable gear has become an attractive possibility. However, the challenge of providing electrical energy for these devices remains, because conventional battery power supplies need frequent replacement or recharging from a land power line, frequently putting the wearable article out of commission for extended periods of time. This is particularly problematic for military and hazardous environment protective gear applications. Specifically, for military applications the additional dangers of high operating temperatures of conventional batteries are a particular issue.

Referring now to FIGS. 8A-8B, exemplary embodiment of inventive clothing or wearable gear articles, each incorporating one ore more novel KEPGs 1110 and/or 1170, each having one or more integrated electrical devices, and each having an optional power output port, for powering additional electrical devices connected thereto, is shown as an upper body wearable article 450 and a lower body wearable gear article 500.

The inventive wearable articles 450, 500 advantageously address the above-described and other challenges by providing a network of novel KEPG generators to generate, store, and deliver primary, supplemental, and/or recharging power, to one or more electrical devices incorporated into the wearable articles 450, 500, and/or to one or more ports located on the articles 450, 500 that may be connected to external electrical devices to power and/or recharge them. The wearable articles 450, 500 are shown as upper and lower body articles, it should be understood that the articles 450, 500 may be readily configured as any other type of wearable article or wearable accessory, such as a hat, helmet, gloves, footwear, a belt, or a harness, without departing from the spirit of the invention.

Referring now to FIG. 8A, an exemplary first embodiment of the inventive clothing or wearable gear article, incorporating one or more novel KEPGs 1110 and/or 1170, having multiple integrated electrical devices, and having an power optional output port for powering additional electrical devices connected thereto, is shown as a wearable upper body article 450.

The wearable article 450, includes a wearable base attire 452 that is worn over the user's torso and that includes a pair of sleeves 454 and 456, each having a respective wrist-terminated cuff region 458 and 460. The base attire 452 may be conventional clothing (e.g., a jacket or a coat); a portion of: a professional functional garment set, such as a firefighter, medical response, law enforcement, or military uniform; or wearable protective gear, such as a environmental hazard (chemical, radiation, and/or biological) suit, or an extra-vehicular activity (EVA) suit for space or underwater exploration. The base attire 452 serves to support, store, and/or conceal the functional and power-generating components of the article 450. The material(s) used in construction of the base attire 452 depend greatly on the application of the wearable article 450, and may include synthetic and/or natural fabrics, leather, polyurethane, Kevlar, nylon, and any other material(s) used for wearable articles. Optionally, instead of being a garment, the base attire 452 may be a harness, for example composed of synthetic webbing, positioned under a conventional clothing or other wearable article (not shown).

The wearable article 450, includes one or more electrically powered devices (shown, by way of example only, as three electrical devices 462-466, even through one or more electrical devices may be readily used). Each of the electrical devices 462-466 may be positioned in any desirable or convenient region of the base attire 452, depending on the particular functionality of the device. Each of the electrical devices 462-466 may be one or more of the following, for example: a media (e.g. AV) player, a monitoring device for monitoring the wearer's medical condition and/or environment outside of the base attire), audiovisual acquisition device and/or recorder, communication gear, computer equipment with and without displays, medical therapy or emergency medication delivery devices, light(s), etc.

Advantageously, the wearable article 450 includes one or more KEPG systems (shown, by way of example only, as four KEPG systems 468-476, even though one or more KEPGs may be readily used, depending on the number of electrical devices (e.g. 462-466), and/or their power requirements). Each of the KEPG systems 462466 may be equivalent to the KEPG 1110 (FIG. 14), the KEPG 1170 (FIG. 15), or to the recharging system 300 of FIG. 5, depending on the available space on, or in, the base attire 452, and desirable characteristics thereof (e.g., weight, flexibility, etc.).

The KEPG systems 468-476 are preferably positioned in areas of the base attire 452 to maximize application of motion thereto, during the wearer's routine physical activities. Thus, for example, it is advantageous to position the KEPG systems 468, 470 in the respective wrist-terminated regions 458, 460 since the wearer's wrist is subjected to a great deal of regular motion, even during simple activities, such as walking. This arrangement maximizes the electrical energy generated by the KEPG systems 460-476.

One or more of the KEPG systems 468-476 may be connected to one or more of the electrical devices 462-466 to power and/or to recharge the devices. Alternately, the wearable article 450 includes a power management unit 478, connected to one or more of the KEPG systems 468-476, and to one or more of the electrical devices 462-466, for aggregating power from KEPGs connected thereto and for routing power to one or more electrical device 462-466 in accordance with a predetermined, user-controlled, and/or a dynamically generated situation-based, protocol. For example, if a medical monitoring electrical device determines that the wear is hurt, and available power is limited, the power management unit 478 may direct available power to a communication electrical device.

The wearable article 450 may also include an optional power output port 480, positioned in a predetermined convenient location on the base attire 452, for providing electrical energy to any external electrical device connected thereto (not shown). The output port 480 may be connected to the power management unit 478 and/or to an optional additional dedicated KEPG system 482.

Referring now to FIG. 8B, an exemplary second embodiment of the inventive clothing or wearable gear article, incorporating one or more novel KEPGs 1110 and/or 1170, having one or more integrated electrical devices, and having an optional power output port for powering additional electrical devices connected thereto, is shown as a wearable lower body article 500,

The wearable article 500 is substantially similar in functionality and operation to the wearable article 450, described above in connection with FIG. 8A, and includes a wearable base attire 502 that is worn over the user's lower body and legs, and that includes a pair of pant legs 504 and 506, each having a respective ankle-terminated cuff region 508 and 510. The base attire 502 may be conventional clothing (e.g., trousers or pants); a portion of: a professional functional garment set, such as a firefighter, medical response, law enforcement, or military uniform; or wearable protective gear, such as a environmental hazard (chemical, radiation, and/or biological) suit, or an extra-vehicular activity (EVA) suit for space or underwater exploration. The base attire 502 serves to support, store, and/or conceal the functional and power-generating components of the article 500. As noted above, with respect to the base attire 452, the material(s) used in construction of the base attire 502 depend greatly on the application of the wearable article 500. Similarly, instead of being a garment, the base attire 502 may be a harness, for example composed of synthetic webbing, positioned under a conventional clothing or other wearable article (not shown).

The wearable article 500, includes one or more electrically powered devices (shown, by way of example only, as an electrical device 512, even through two or more electrical devices may be readily used). The electrical device 512 (which may be any device as described above in connection with electrical devices 462-466 (FIG. 8A) may be positioned in any desirable or convenient region of the base attire 502, depending on the particular functionality of the device.

Advantageously, the wearable article 500 includes one or more KEPG systems (shown, by way of example only, as three KEPG systems 514-518, even though one or more KEPGs may be readily used, depending on the number of electrical devices (e.g. 512), and/or their power requirements). Each of the KEPG systems 514-518 may be equivalent to the KEPG 1110 (FIG. 14), the KEPG 1170 (FIG. 15), or to the recharging system 300 of FIG. 5, depending on the available space on, or in, the base attire 502, and desirable characteristics thereof (e.g., weight, flexibility, etc.).

The KEPG systems 514-518 are preferably positioned in areas of the base attire 502 to maximize application of motion thereto, during the wearer's routine physical activities. Thus, for example, it is advantageous to position the KEPG systems 514, 516 in the respective ankle-terminated regions 508, 500 since the wearer's ankles are subjected to a great deal of regular motion, even during simple activities, such as walking. This arrangement maximizes the electrical energy generated by the KEPG systems 514-518.

Similarly to the wearable article 450 (FIG. 8A), the wearable article 500, may be configured to enable one or more of the KEPG systems 514-518 may be connected to the electrical device 512 td power and/or to recharge the device.

The wearable article 500 may also include an optional power output port 522, positioned in a predetermined convenient location on the base attire 500, for providing electrical energy to any external electrical device connected thereto (not shown). The output port 522 may be connected to an optional additional dedicated KEPG system 524. Optionally, the wearable article 500 may include a power management unit 520, connected to one or more of the KEPG systems 514-518, and to the electrical device 512 and/or to the output port 522. The power management unit 520 is substantially similar to the power management unit 478 of FIG. 8A.

The wearable articles 450 and 500 are shown as separate items by way of example only—it should be noted, that as a matter of design choice, without departing from the spirit of the present invention, the articles 450 and 500 may be readily combined into a single upper and lower body article and may include other wearable gear accessories (not shown), such as: gloves, footwear, and headgear (helmet, etc.), to advantageously provide a complete suit with built-in electrical devices and optional power output ports, capable of generating power, for one or more of the built-in or connected electrical devices, from motion of the wearer. Alternately, one of the inventive wearable articles 450, 500, may be combined with a conventional wearable article.

The combined suit (not shown), including one or both of the wearable articles 450, 500, may optionally be configured as military wearable combat gear (e.g., field fatigues), or as wearable protective gear, such as an environmental hazard (chemical, radiation, and/or biological) suit, or an extra-vehicular activity (EVA) suit for space or underwater exploration. This may be accomplished by environmentally sealing the combined suit along with the wearable gear accessories (gloves, footwear, helmet, etc.). In this arrangement, the inventive wearable articles 450, 500 are particularly advantageous because military and protective gear greatly benefit from including one or more mission-critical electrical devices (e.g., monitoring devices (wearers medical condition and/or environment), AV acquisition and/or recorders, communication gear, computer equipment with and without displays, medical therapy or emergency medication delivery devices, light(s), etc.).

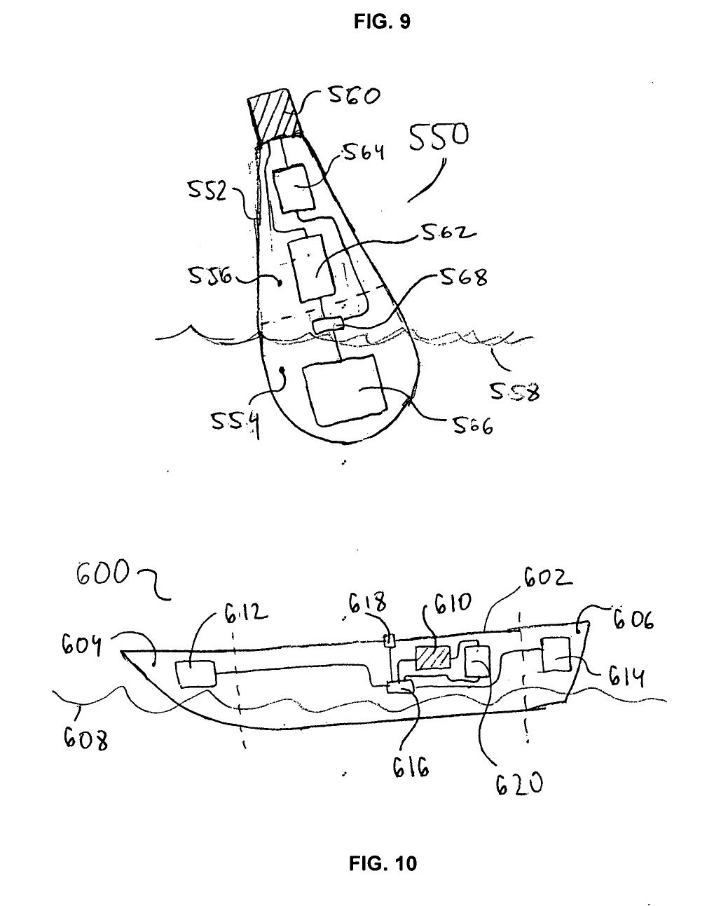

Referring now to FIG. 9, an exemplary embodiment of a marine floating structure having one or more functional components and an optional rechargeable battery system, and incorporating one or more novel KEPGs 1110 and/or 70, is shown as a marine structure 550.

The marine floating structure 550, may be a buoy or any other form of a remote marine structure that provides one or more functions, and that is powered by electrical energy. In configuration and operation, with respect to KEPG utilization and electrical energy management, the marine floating structure 550 is substantially similar to the device 150 of FIG. 2, with several differences as noted below. The floating structure 550 includes a housing 552 with two sections: a submerged section 554 (substantially submerged under a waterline 558), and an elevated section 556, positioned above the submerged section 554.

The floating structure 550 includes a functional component 560 (which optionally may include two or more functional sub-components) for performing the intended functions of the floating structure 550 (for example, the functional component 560 may include an electrically powered light and/or a wireless transmitter or repeater), one or more KEPG systems (shown by way of example as KEPG systems 566 and 564) for providing electrical energy to an electrical energy aggregating unit 568, in response to motion of the floating structure 550, and an optional rechargeable power supply 562 for providing electrical energy to the functional component 560 under predefined conditions, for example, when the floating structure 550 is immobile.

Each of the KEPG systems 566 and 568 is substantially equivalent to the KEPG system 162 of FIG. 2, and may each include any number of multiple KEPG sub-systems. While two KEPG systems are shown in FIG. 9, one or more KEPG systems may be utilized as a matter of design choice. If a single KEPG system is used, then the aggregating unit 568 is not necessary.

Because the elevated section 556 has the widest range of reciprocating generally horizontal motion, in response to mechanical disturbances of the housing 502, at a point furthest from the waterline 558, preferably, the KEPG system 564 is positioned therein and oriented to maximize the benefit from horizontal reciprocating motion. Conversely, the submerged section 554 is generally subjected to vertical reciprocating motion, and thus, preferably, the KEPG system 566 is positioned therein and oriented to maximize the benefit from vertical reciprocating motion.

The aggregating unit 568 and the rechargeable power supply 562, are substantially similar in connection scheme, operation, and functionality to the aggregating unit 170 and the rechargeable power supply 158 of FIG. 2, respectively, and thus need not be described herein.

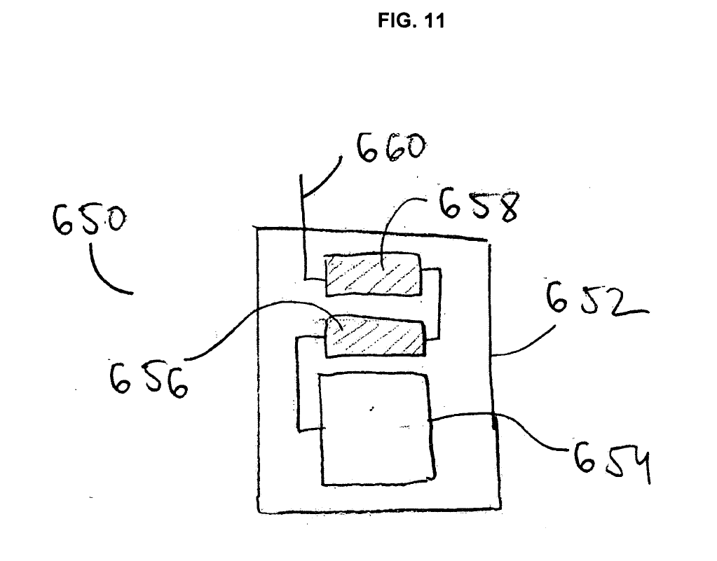

Referring now to FIG. 11, an exemplary embodiment of a watercraft having one or more functional components and/or a power output port for powering an electrical device connected thereto, an optional rechargeable battery system, and incorporating one or more novel KEPGs 1110 and/or 1170, is shown as a watercraft 600. The watercraft 600, may be an inflatable boat, a row boat, or any other form of a watercraft that is supplied with an electrical device and/or a port for powering and/or recharging an electrical device connected thereto. In configuration and operation, with respect to KEPG utilization and electrical energy management, the watercraft 600 is substantially similar to the device 150 of FIG. 2, with several differences as noted below.

The watercraft 600 includes a hull 604, having two sections: a front section 604 and a rear section 606, a functional component 610 (which optionally may include two or more functional sub-components) for providing desirable peripheral functions to the watercraft 600 (for example, the functional component 610 may include an electrically powered light, a radio, a media player, an emergency SOS transmitter, and/or a sonar), one or more KEPG systems (shown by way of example as KEPG systems 612 and 614) for providing electrical energy to an electrical energy aggregating unit 616, in response to motion of the watercraft 600, and an optional rechargeable power supply 620 for providing electrical energy to the functional component 610 under predefined conditions, for example, when the watercraft 600 is immobile, or in an emergency (e.g. to power an SOS transmitter).

Each of the KEPG systems 612 and 614 is substantially equivalent to the KEPG system 162 of FIG. 2, and may each include any number of multiple KEPG sub-systems. While two KEPG systems are shown in FIG. 11, one or more KEPG systems may be utilized as a matter of design choice. If a single KEPG system is used, then the aggregating unit 616 is not necessary.

Because the section 604 has the widest range of reciprocating generally vertical motion at a point furthest from the rear section 606, in response to movement of the watercraft 600 through a body of water 608, preferably, the KEPG system 612 is positioned therein and oriented to maximize the benefit from vertical reciprocating motion. Conversely, the rear section 606 is generally subjected to horizontal reciprocating motion, and thus, preferably, the KEPG system 614 is positioned therein and oriented to maximize the benefit from horizontal reciprocating motion.

The aggregating unit 616 and the rechargeable power supply 620, are substantially similar in connection scheme, operation, and functionality to the aggregating unit 170 and the rechargeable power supply 158 of FIG. 2, respectively, and thus need not be described herein.

The watercraft 600 may also include an optional power output port 618, connected to the aggregating unit 616, for powering an electrical device connected thereto. The port 618 may be useful to provide the electrical energy generated by the KEPG systems 612, 614 to an electrical device that is not part of the watercraft's functional component 610. Thus, a user may connect their mobile telephone to the port 618 to recharge it.

Referring now to FIG. 11, an exemplary embodiment of a motion sensor utilizing a KEPG to generate a signal responsive to a mechanical disturbance applied thereto, is shown as a motion sensor 650. The motion sensor 650, includes a housing 652, a KEPG system 654 for generating an electrical signal when a mechanical disturbance (i.e., motion) is applied to the housing 652, an indicator unit 656, electrically connected to the KEPG system 654, for indicating the presence of the mechanical disturbance in response to presence of the signal received from the KEPG system 654, in one or more of the following modes: visually (e.g. an LED), audibly (e.g. via a speaker), and by generating a data signal that may be interpreted as indicating motion of the sensor 650 by a connected remote system (not shown).

Optionally, the indicator unit 656 may be configured to interpret the strength of the received electrical signal, and to determine the severity of the mechanical disturbance therefrom. In this case, the indicating modes described above, are preferably configured to communicate the severity of the disturbance. For example, an increasing severity of mechanical disturbance may produce a blinking or more intensely glowing light, a louder or different audio tone, or a data set containing severity data.

An optional transmission unit 658 supplied with a transmission link 960, may be connected to the indicator unit 656 to enable transmission of indicator data or of other audio or visual indicators to a remote location. The transmission unit 658 may be a wireless transmitter (with the link 960 as an antenna) to transmit indicator data to a remote wireless receiver, or it may be a simple output connector with the link 960 as a simple wire connected to a remote, lamp, speaker, or electronic device.

The sensitivity (in terms of motion severity and direction) of the motion sensor 650 may be configured as a matter of design choice by selecting an appropriate KEPG system 654 and positioning it in an optimal location in the housing 652. The KEPG system 654 may include a single KEPG 1110, or may include multiple KEPGs 1110 (of the same or of different sizes, and oriented in the same or different directions) distributed throughout the housing 652 in desirable locations. For very specific (such as law enforcement or military) applications, it may be advantageous to provide the KEPG system 654 with specially configured oscillating weights (e.g. weight(s) 1120 of FIG. 14) that are extremely sensitive to motion in a particular direction or than have a very high motion threshold, depending on the sensor 650 application. Other applications of the motion sensor 650 include, but are not limited to: toys (e.g. a stuffed toy where the indicator 656 produces a music or speech audio signal, in response to the child moving or playing with the toy sufficiently to cause the KEPG system 654 to generate an electrical signal); vehicle alarms, and earthquake sensors.

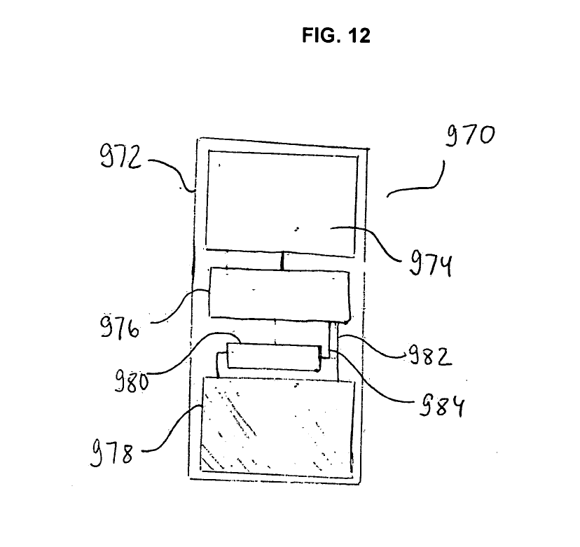

Referring now to FIG. 12, an exemplary embodiment of a inventive electrical device capable of dual mode KEPG-based power generation, is shown as an electrical device 970. One of the drawbacks of even the novel KEPGs 1110, 1170 is that they only function in response to motion of a device in which they are installed. In accordance with the present invention, the electrical device 970 is advantageously capable of utilizing the power-generation capabilities of one or more integrated KEPGs, even when the device 970 is stationary.

The device 970 may be substantially similar in configuration and functionality to the electrical devices 100, 150, and/or 200 described above in connection with FIGS. 1, 2, and 3, with respect to a housing 972, a functional component 978 (which may include more than one functional sub-components), and a rechargeable power supply 980. However, the device 970 differs from the devices 100, 150, and 200 in two important ways—first the device 970 includes a at least one user-operable operable mechanical input element 974 (for example a keyboard, keypad, or individual buttons) positioned on an outer surface of the housing 972, and also includes a KEPG-based dual mode electrical generator 976 for selectively generating, storing, and/or delivering electrical energy, to one or more functional components of the device, and/or for selectively recharging the rechargeable battery system, in response both to motion of the device 970, and also to operation of the at least one mechanical input element 974 by the user.

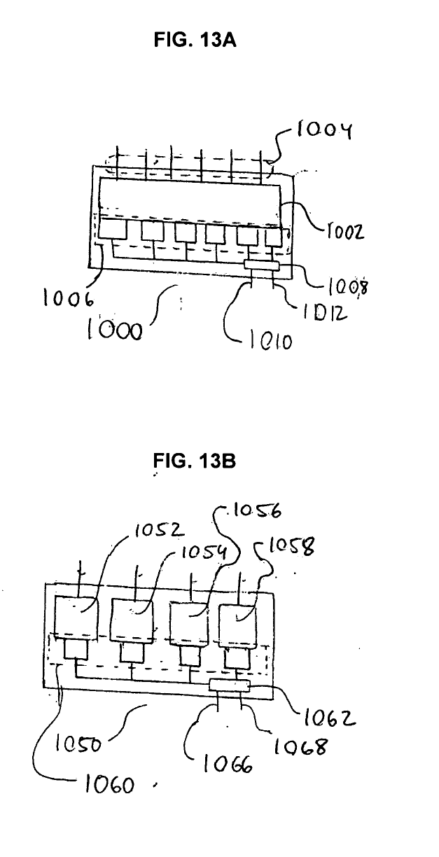

The purpose of the dual mode electrical generator 976, several embodiments of which are described in greater detail below in connection with FIGS. 13A-13B, is to generate electrical energy both from motion of the device 976 and also from repetitive operation of the at least one mechanical input element 974. This goal is advantageously accomplished, by the generator 976, by converting operation of one or more mechanical input elements 974 into a mechanical disturbance applied to one or more KEPGs to simulate the effect of motion on the device 970, even when the device 970 is stationary. Accordingly, the electrical energy is generated by the generator 976 as follows:

When the device 970 is stationary, in response to user's repetitive activation of one or more mechanical input elements 974 (e.g., if the device 970 is a notebook computer, being used by a stationary user, typing on the keyboard (i.e., element 974) causes the generator 976 to produce electrical energy);

When the device 970 is moving, but inactive, in response to motion thereof (e.g., if the device 970 is a media player, being carried by a walking user, causes the generator 976 to produce electrical energy); and

When the device 970 is moving and active, in response both to motion thereof and also to user's repetitive activation of one or more mechanical input elements 974 (e.g., if the device 970 is a handheld video game console, being used by a user riding a watercraft, repeatedly pressing game control keys (i.e., element 974), causes the generator 976 to produce electrical energy both from the motion of the watercraft and from the user's game-playing activity.

As noted above, the one or more mechanical input elements 974, may be a keyboard (such as a notebook keyboard), a keypad (for example on a mobile telephone, a calculator, or on a portable data reader), or one or more individual buttons (such as control buttons on a handheld game console).

Referring now to FIG. 13A, a first embodiment of the dual mode electrical generator 976 is shown as a generator 1000. The generator 1000 includes a mechanical converter system 1002, having a mechanical connection 1004 to the one or more pre-selected mechanical input elements 974, for converting operation of the input element(s) 974 into a mechanical disturbance and for applying the mechanical disturbance to a KEPG system 1006 connected thereto. The KEPG system 1006 preferably includes one or more KEPGs 1110 and/or 1170. If the KEPG system 1006 includes more than one KEPG, then the generator 1000 also preferably includes an electrical energy aggregating unit 1008 connected thereto, substantially similar to the electrical energy aggregating unit 170 of FIG. 2. The aggregating unit 1008 (or the KEPG system 1006, if the unit 1008 is not used), preferably includes one or more of the following power links: a power link 1010 for delivering electrical energy to the one or more functional components 978, or a power link 1012 for delivering electrical energy to the one or more functional components 978 to the rechargeable power supply 980.

The mechanical converter system 1002, preferably delivers the mechanical disturbance directly to a KEPG's oscillating weight. The converter system 1002 may be any device for translating pressure motion into a mechanical disturbance in a different coordinate plane corresponding to the plane of motion of a KEPG's oscillating weight. For example, the converter system 1002 may be a membrane with a negative pressure under the mechanical input elements 974, connected through a spring and gear train to the KEPG system 1006.

Referring now to FIG. 13B, a second embodiment of the dual mode electrical generator 976 is shown as a generator 1050. The generator 1050 includes multiple mechanical converter systems, shown by way of example as converter systems 1052-1058 (even though two or more converter systems may be used), each having a mechanical connection to a corresponding single pre-selected mechanical input element 974, or to a group thereof, each configured for converting operation of the corresponding input elements 974 into a mechanical disturbance, and configured for applying the mechanical disturbance to a corresponding KEPG system 1060 connected thereto. The KEPG system 1060 preferably includes one or more KEPGs 1110 and/or 1170 that may be optionally connected to an individual converter system 1052, 1054, 1056, or 1058. If the KEPG system 1060 includes more than one KEPG, then the generator 1050 also preferably includes an electrical energy aggregating unit 1062 connected thereto, substantially similar to the electrical energy aggregating unit 170 of FIG. 2. The aggregating unit 1062 (or the KEPG system 1060, if the unit 1062 is not used), preferably includes one or more of the following power links: a power link 1066 for delivering electrical energy to the one or more functional components 978, or a power link 1068 for delivering electrical energy to the rechargeable power supply 980.

The mechanical converter system 1050, preferably delivers the mechanical disturbance directly to a KEPG's oscillating weight. The converter system 1050 may be any device for translating pressure motion into a mechanical disturbance in a different coordinate plane corresponding to the plane of motion of a KEPG's oscillating weight. For example, the converter system 1050 may be a membrane with a negative pressure under the mechanical input elements 974, a hinged joint member assembly, or a pneumatic piston, to the KEPG system 1060.

Referring now to FIGS. 14 and 15, the KEPGs that are preferred for utilization in conjunction with the above-described inventive embodiments of FIGS. 1-13B, and that are disclosed in the above-incorporated Bednyak patent applications are shown. In essence, the novel oscillating weight utilized by the various embodiments of the Bednyak KEPGs, achieves its superior and advantageous characteristics through an interior hollow cavity with a freely mobile acceleration element disposed therein. When a KEPG with the novel oscillating weight is subjected to motion, the movement of the acceleration element within the cavity greatly increases the likelihood, the duration, the acceleration, and the angular range of motion of the oscillating weight, resulting in a greater response to the motion of the KEPG and thus lowering the motion threshold as well as increasing the overall efficiency of the KEPG. Because of the action of the acceleration element, the novel oscillating weight provides a performance that is vastly superior to conventional weights that are of significantly greater size, and thus enable advantageous utilization of the novel KEPG in applications that were previously impractical.

Referring now to FIG. 14, an exemplary first embodiment of a KEPG preferably utilized in conjunction with the various embodiments of the present invention previously described in conjunction with FIGS. 1-13B, for generating, delivering, and/or storing electrical energy, is shown as a KEPG 1110. As noted above, the KEPG 1110 is described in greater detail in the above-incorporated Bednyak U.S. patent application. However, a general description of its key features is substantially reproduced herein for the sake of convenience. For a more in-depth and detailed description of the KEPG 1110 and the various embodiments of components thereof, reference should be made to the Bednyak application FIGS. 1-2, and FIGS. 4A-11.

The KEPG 1110 includes a support structure 1112 for retaining and supporting the various components of the KEPG 1110 and interconnections thereof, and an electrical energy generation component 1114 for generating electrical energy from motion of the KEPG 1110, one or more power interfaces 1130, 1134 for delivering electrical energy to an external electrical device (not shown), and also may include one or more optional components, electrically connected between the electrical energy generation component 1114 and the power interfaces 1130, 1134, such as optional electrical energy processing units 1126, 1132, and/or an optional electrical energy storage unit 1128.

The support structure 1112 may be a completely or partially enclosed housing, or an open framework, for example, when the KEPG 1110 is built into, and integrated with internal components of, an electrical device. The electrical energy generation component 1114, includes a electromechanical transducer 1118 for generating electrical energy from rotational motion delivered thereto, and a rotational motion generation component 1116, mechanically connected to the transducer 1118, for generating rotational motion from motion of the KEPG 1110, for delivery to the transducer 1118.

The transducer 1118 may be any electromechanical device that implements the well known Faraday's principle of induction. For example the transducer 1118 may include a conductive coil ring or tube (e.g., a ring or a cylinder wrapped in conductive wire) and a magnetized rotor mounted therein (not shown) in such a manner as to enable radial rotation of the coil and rotor relative to one another, so that when rotational motion is delivered to the rotor or to the coil, their relative motion to one another causes the coil to advantageously produce electrical energy.

The rotational motion generation component 1116 includes an oscillating weight 1120, for generating oscillating motion in response to motion of the KEPG 1110, a pivot element 1122, mechanically connected to the oscillating weight 1120, for producing a reciprocating radial motion in response to the oscillating motion of the oscillating weight 1120, and a motion conversion component 1124, mechanically connected to the pivot element 1122, for translating the reciprocating radial motion, delivered by the pivot element 1122 thereto, into rotational motion for delivery to the transducer 1118. The oscillating weight 1120, is preferably capable of a high degree of acceleration relative to its size, a wide range of radial motion, and having a minimized motion threshold. Optionally, the support structure 1112 may include an open or transparent viewing region proximal to the oscillating weight 1120, to enable viewing of the operation of the weight 1120.

The support structure 1112 may be supplied with an optional viewing area 1142 for viewing operation of the oscillating weight 1120, that may be made visible to the user (for example, through a corresponding viewing area in the housing of an electrical device in which the novel KEPG is installed (not shown). In this case, oscillating weight 1120 may include decorative features on its visible surface, as shown and described in conjunction with FIGS. 8-11 of the Bednyak patent application.

The pivot element 1112, may be a rod rotatably retained by a holding element (not shown) and connected to the motion conversion component 1124 at one end and to the oscillating weight 1120 at the other end, in such a manner that oscillating motion of the oscillating weight 1120 produces reciprocating radial motion of the rod about its longitudinal axis. By way of example, the motion conversion component 1124, may be a mechanical gear and/or spring assembly, having an exemplary input drive element 1136 for receiving reciprocating radial motion from the pivot element 1122, an exemplary gear and/or spring assembly 1138 mechanically connected to the input drive element 1136, that is configured and adapted for converting the reciprocating radial motion delivered by input drive element the into desirable rotational motion, and an exemplary output drive element 1140, mechanically connected to the gear and/or spring assembly 1138, for delivering the rotational motion from the assembly 1138 to the transducer 1118. Of course, a motion conversion mechanism of any other type or construction may be readily and advantageously utilized as the motion conversion component 1124 as long as it is capable of translating reciprocating radial motion into rotational motion.

The KEPG 1110 may be configured, as matter of design choice, to simply deliver generated electrical energy as it is produced by the electrical energy generation component 1114 to an external electrical device for external processing (i.e. rectification, transformation, etc.) in which case a power interface 1130, electrically connected to the transducer 1118, may be utilized. The power interface 1130 may be any electrical connector, capable of transmitting electrical energy therein.

Optionally, the KEPG 1110 may be configured to process the generated electrical energy internally before delivering it to an outside electrical device via the power interface 1130. In this case, the optional electrical energy processing unit 1132 is electrically connected between the transducer 1118 and the power interface 1130. The electrical energy processing unit 1132 may include various electrical energy processing functionality as a matter of design choice. For example, the processing unit 1132 may include rectification circuitry (not shown) for rectifying the received electrical energy to produce direct current (DC) electrical energy, or transformer circuitry (not shown) for changing the voltage of the electrical energy to a desirable magnitude. Other forms of electrical energy processing may be implemented in the processing unit 1132 as a matter of design choice or necessity.

Alternately, or additionally, the KEPG 1110 may be configured to temporarily store the generated electrical energy for future delivery to an external electrical device. In this case, the optional electrical energy processing unit 1126 is electrically connected between the transducer 1118 and the electrical energy storage unit 1128, which in turn is connected to the power interface 1130. Optionally, the electrical energy storage unit 1128 may be connected to an optional individual power interface 1134 (substantially identical to the power interface 1130). Alternately, the electrical energy processing units 1126, 1132 may be implemented as a single device electrically connected to both the transducer 1118, and to the electrical energy storage unit 1128.

The electrical energy storage unit 1128 may be any electrical energy storage device or assembly, such as one or more capacitors, for temporary low-loss storage of electrical energy. In one configuration, the electrical energy storage unit 1128 may output electrical energy to one of the power interfaces 1130, 1134 when it reaches its maximum storage capacity, and then continue the cycle of accumulation of electrical energy from the transducer 1118 and subsequent release.

Alternately, the electrical energy storage unit 1128 may deliver the stored electrical energy to an outside electrical device only in response to the device drawing or otherwise signaling a request for that energy. For example, if the KEPG 1110 is implemented in a mission-critical device, such as a pacemaker, the device may be configured to draw on the electrical energy stored in the electrical energy storage unit 1128 only when the device's primary source of electrical energy fails.

Thus, in its various alternate configurations, the KEPG 1110 may provide a wide variety of outputs:

unprocessed electrical energy from the power interface 1130, as it is generated by the electrical energy generation component 1114;

processed electrical energy from the power interface 1130, as it is generated by the electrical energy generation component 1114 and processed by the electrical energy processing unit 1132;

processed electrical energy from the power interface 1130, received from the electrical energy storage unit 1128, that was previously generated by the electrical energy generation component 1114 and processed by the electrical energy processing unit 1126;

unprocessed electrical energy from the power interface 1130, as it is generated by the electrical energy generation component 1114; and processed electrical energy from the power interface 1130, received from the electrical energy storage unit 1128, that was previously generated by the electrical energy generation component 1114 and processed by the electrical energy processing unit 1126;

processed electrical energy from the power interface 1130, as it is generated by the electrical energy generation component 1114 and processed by the electrical energy processing unit 1132, and processed electrical energy from the power interface 1130, received from the electrical energy storage unit 1128, that was previously generated by the electrical energy generation component 1114 and processed by the electrical energy processing unit 1126;

Referring now to FIG. 15, an exemplary alternate embodiment of the inventive KEPG 1110 of FIG. 14, also preferably utilized in conjunction with the various embodiments of the present invention previously described in conjunction with FIGS. 1-13B, for generating, delivering, and/or storing electrical energy, is shown as a KEPG 70. The KEPG 1170 is described in greater detail in the above-incorporated Bednyak U.S. patent application, however a general description of its key features is substantially reproduced herein for the sake of convenience. For a more in-depth and detailed description of the KEPG 1170 and the various embodiments of components thereof, reference should be made to the above-incorporated Bednyak patent application FIGS. 3-11).

Referring now to FIG. 15, an exemplary second embodiment of the novel KEPG, utilizing multiple coupled KEPG sub-systems, is shown as a KEPG 70. The KEPG 1170 includes a support structure 1172, such as a housing or a framework, a KEPG system 1174 that includes two or more KEPG sub-systems (shown as KEPG subsystems 1176-1188 by way of example), an electrical aggregating unit 1190, for aggregating electrical energy received from the KEPG system 1174 (i.e. from KEPG sub-systems 1176-1188), and optionally for processing the aggregated electrical energy, and a power interface 1192 for delivering electrical energy to an external electrical device (not shown). The KEPG 1170 may also include an optional electrical energy storage unit 1194 electrically connected between the electrical aggregating unit 1190 and an optional power interface 1196.

While the KEPG system 1174 is shown as having seven KEPG sub-systems 1176-1188 in FIG. 15, it should be understood that any number of two or more KEPG sub-systems may be readily utilized as a matter of design choice to improve the performance of the KEPG 1170, limited only by the design considerations, such as a desired size and/or other physical constraints, thereof.

Each of the KEPG sub-systems 1176-1188, is preferably substantially similar to the KEPG 1110 of FIG. 14, but other types of KEPGs may be utilized as well. The electrical aggregating unit 1190 may include any type of electrical circuitry configured for simultaneously receiving electrical energy from multiple sources and aggregating the received energy before forwarding the aggregated energy to another component (i.e., to the power interface 1192, or to the optional electrical energy storage unit 1194).

The configuration of the electrical aggregating unit 1190 also depends on the configuration of the KEPG sub-systems 1176-1188. For example, if the KEPG sub-systems 1176-1188 are configured without electrical energy processing (e.g. without electrical energy processing units 1126 and/or 1132 of FIG. 14), the electrical aggregating unit 1190 may include an electrical energy processing unit (substantially similar to the processing units 1126 and/or 1132 of FIG. 14) for processing the aggregated unprocessed electrical energy received therefrom.

The optional electrical energy storage unit 1194 is substantially similar to the electrical energy storage unit 1128 of FIG. 14, except that it may be of larger capacity to provide electrical energy storage for energy received from multiple KEPGs. Similarly, the electrical energy storage unit 1194 is connected to the optional power interface 1196 for selectively delivering stored electrical energy to an external electrical device (not shown).

The KEPG 1170 is capable of providing a greater amount of electrical energy than a single KEPG 1110 of FIG. 14. In addition, optionally, the individual KEPG sub-systems may be located outside the support structure 1142, and distributed throughout an electrical device, or another structure, to maximize the mechanical disturbance applied to each KEPG sub-system during motion. It should be noted that the KEPG 1170 may be readily substituted for the KEPG 1110, subject to size considerations, in any of the inventive embodiments shown in FIGS. 1-13A.

The KEPG 1110 and KEPG 1170 may be readily utilized in virtually any electrical device, electrical device accessory, and/or article or structure incorporating one or more electrical devices. Various embodiments of the present invention utilizing one or more KEPG 1110 and/or KEPG 1170 subsystems in a wide variety of exemplary applications are shown and described below in connection with FIGS. 1-13A.

As shown in FIGS. 4A-11, of the above-incorporated Bednyak patent application, the key feature of the various embodiments of the novel oscillating weight of the present invention, is an internal cavity defined along the length of the weight and in the same plane as the direction of the weight's oscillating motion, and a freely moving acceleration element located in the cavity, that moves within the cavity from one end of the weight to another, in response to a mechanical disturbance (i.e. motion) applied to the oscillating weight. The independent motion of the acceleration element greatly increases the acceleration and momentum of the oscillating weight and enables a greater range of radial motion as well as a significantly lower motion threshold for the weight.

Because the KEPGs 1110, 1170 include oscillating weights 1120 that oscillate in a particular coordinate plane, when utilizing the KEPGs 1110, 1170 in an electrical device, it would be advantageous to position and orient them in such a manner as to maximize the likelihood and the duration of motion that exceeds the motion threshold. For example, if the KEPGs 1110, 1170 are utilized in a floating buoy to power electrical lights, the KEPGs 1110, 1170 should be positioned near the top of the buoy and oriented with the weight 1120 plane of motion perpendicular to the water surface, as that area has the greatest likelihood and range of side-to-side motion that would result in desirable oscillating motion of the weight(s) 1120.

The KEPGs 1110 and 1170 of FIGS. 14 and 15, provide many peripheral advantages as a result of their novel construction and operation, including, but not limited to:

Lower operating temperature than conventional portable device power supplies (especially fuel cells): This makes the novel KEPGs particularly suitable for military applications where low equipment temperatures can provide an increased defense against temperature-sensitive enemy surveillance, reconnaissance, and/or targeting;

Reduced reliance on conventional batteries and reduction of consumption of local utility electrical resources: The ability of the novel KEPGs 1110, 1170 to provide energy to power electrical devices and/or recharge device batteries from motion, reduce the need for conventional lead acid batteries which are environmentally unsafe and expensive to dispose when expended, as well as reduce the frequency with which users draw on local electrical utilities to recharge their electrical devices—a particularly important advantage in times when lower electrical energy consumption is highly desirable.

Thus, while there have been shown and described and pointed out fundamental novel features of the invention as applied to preferred embodiments thereof, it will be understood that various omissions and substitutions and changes in the form and details of the devices and methods illustrated, and in their operation, may be made by those skilled in the art without departing from the spirit of the invention. For example, it is expressly intended that all combinations of those elements and/or method steps which perform substantially the same function in substantially the same way to achieve the same results are within the scope of the invention.

I claim:

1. A power supply, for use with a device of predetermined functionality having a housing and at least one functional component, disposed therein, that implements the predetermined functionality, the at least one functional component selectively requiring electrical power in response to operation of the device, the power supply being disposed within the housing, and comprising:
at least one kinetic electrical generator, disposed within the housing, each said at least one kinetic electrical power generator being operable to:
generate electrical energy in response to motion of the housing that exceeds a predefined motion threshold, and
process said electrical energy into electrical output power, said electrical output power corresponding to at least a first portion of the required electrical power; and
power output means, connected to said at least one kinetic electrical generator, for delivering said electrical output power from said at least one kinetic electrical generator, to the at least one functional component during the device operation.

2. The power supply of claim 1, wherein each said at least one kinetic electrical generator, comprises:
a support structure;
a pivot element, disposed within said support structure;
an oscillating weight, disposed within said support structure, having a top portion connected to said pivot element, and a bottom portion, said oscillating weight being configured and operable to achieve oscillating motion in an angular range in response to motion of the housing that exceeds said predefined motion threshold, said pivot element being operable to produce a reciprocating radial motion thereof, in response to said oscillating motion of said oscillating weight;
acceleration means, disposed within said oscillating weight, for decreasing said predefined motion threshold, and for increasing said angular range of said oscillating motion of said oscillating weight in response to said motion of the housing;
motion conversion means, connected to said pivot element, for translating said reciprocating radial motion into a rotational motion of a first velocity;
electromechanical transducer means, connected to said motion conversion means, for generating electrical energy in response to said rotational motion applied by said motion conversion means thereto;
electrical energy processing means, connected to said electromechanical transducer means, for modifying said electrical energy into said electrical output power; and
electrical output means, connected to said electrical energy processing means, for transferring said electrical output power from said electrical energy processing means to said power output means.

3. The power supply of claim 2, wherein at least one of said at least one kinetic electrical generator further comprises energy storage means, disposed within said support structure and connected to said electrical energy processing means, for:
when the device is not operating, storing said output electrical power;
when the device is operating and the housing is not in motion, providing said electrical output power to at least one functional component, and
when the device is operating and the housing is in motion, providing said electrical output power to at least one functional component, and when said electrical output power exceeds the required electrical power by an excess power amount, storing said excess power amount.

4. The power supply of claim 1, further comprising:
a rechargeable power unit, disposed within the housing and connected between said at least one kinetic electrical generator, and the at least one functional component, operable to:
store electrical power in an amount of less than or equal to a predetermined maximum power storage capacity; and
provide said stored electrical power to the at least one functional component during the device operation, in an amount corresponding to at least a second portion of the required electrical power.

5. The power supply of claim 4, wherein said rechargeable power unit is further operable to:
when said stored electrical power amount is below said predetermined maximum power storage capacity, receive said electrical output power from said at least one kinetic electrical generator until said predetermined maximum power storage capacity is reached.

6. The power supply of claim 4, wherein said rechargeable power unit is further operable to:
when a current power capacity is at said predetermined maximum power storage capacity, dissipate said electrical output power received from said at least one kinetic electrical generator.

7. The power supply of claim 4, further comprising:
a back-up power supply, positioned within the housing, and connected to the at least one functional component; operable to:
when said stored electrical power is below said at least a second portion of the required electrical power, providing back-up electrical power to the at least one functional component.

8. The power supply of claim 7, wherein said back-up power supply comprises:
at least one secondary kinetic electrical generator, disposed within the housing, each said at least one kinetic electrical power generator being operable to:
generate electrical energy in response to motion of the housing that exceeds a predefined motion threshold;
process said electrical energy into electrical output power, said electrical output power corresponding to at least a first portion of the required electrical power; and
store said electrical output power as back-up electrical power.

9. The power supply of claim 1, wherein the at least one functional component comprises a plurality of functional components, wherein said at least one kinetic electrical generator comprises a plurality of kinetic electrical generators, and wherein at least a portion of said plural kinetic electrical generators, is connected to different plural functional components.

10. The power supply of claim 1, wherein said at least one kinetic electrical generator comprises a plurality of kinetic electrical generators, wherein said power output means further comprises:
an electrical energy aggregation unit, connected to each said plural kinetic electrical generator and positioned within the housing, operable to aggregate said electrical output power from each said plural kinetic electrical generator.

11. A device of a predetermined functionality requiring electrical power, capable of generating at least a portion of the required electrical power having at least one predetermined parameter from motion thereof, the device comprising:
a housing;
operational means for providing said predetermined functionality to a user of the device, said means for providing being at least partially positioned within said housing, and having at least one power input interface;
at least one kinetic electrical generator, disposed within said housing, each said at least one kinetic electrical generator comprising:
a support structure;
a pivot element, disposed within said support structure;
an oscillating weight, disposed within said support structure, having a top portion connected to said pivot element, and a bottom portion, said oscillating weight being configured and operable to achieve oscillating motion in an angular range in response to motion of said support structure that exceeds a motion threshold, said pivot element being operable to produce a reciprocating radial motion thereof, in response to said oscillating motion of said oscillating weight;
acceleration means, disposed within said oscillating weight, for decreasing said motion threshold, and for increasing said angular range of said oscillating motion of said oscillating weight in response to said motion of said support structure;
motion conversion means, connected to said pivot element, for translating said reciprocating radial motion into a rotational motion of a first velocity;
electromechanical transducer means, connected to said motion conversion means, for generating electrical energy in response to said rotational motion applied by said motion conversion means thereto; and
electrical output means for receiving said generated electrical energy from said electromechanical transducer means;
electrical energy processing means, connected to said electrical output means and positioned within said housing, for modifying said generated electrical energy into electrical output power corresponding to the at least one predetermined parameter; and
power means, connected to said electrical energy processing means and to said at least one power input interface, for delivering said electrical output power to said at least one power input interface, said delivered electrical output power at least in part comprising the required electrical power.

12. The apparatus of claim 11, wherein said power means further comprises electrical energy storage means for temporarily storing said electrical output power until a predetermined storage capacity is reached, and thereafter delivering said electrical output power to said at least one power input interface.

13. The apparatus of claim 11, wherein said power means further comprises at least one additional source of electrical power, operable to provide at least a portion of the required electrical power.

14. The apparatus of claim 13, wherein said at least one additional source of electrical power comprises at least one of: a battery, a rechargeable battery, a solar cell, a piezo-electric transducer-based generator, a fuel-based generator, a wind-based generator, a hydro-based generator, and a kinetic-based electrical generator.

15. The apparatus of claim 11, wherein said operational means comprise a plurality of functional components, each plural component being operable to perform a predetermined individual function and requiring individual electrical power, wherein said at least one kinetic electrical power generator comprises a plurality of kinetic electrical power generators, wherein at least one plural kinetic electrical power generator is connected to said power means, wherein said power means is connected to at least one of said plural functional components, and wherein a different at least one plural kinetic electrical generator is connected to a corresponding different at least one of said plural functional components.

16. A self-recharging power supply, for use with a device requiring electrical power and having a power supply input interface with at least one predefined electrical input parameter, comprising:
a power supply housing;
at least one rechargeable power supply element disposed within said power supply housing operable to store electrical power, in a power storage amount up to a maximum capacity, having at least one predefined electrical storage parameter;
at least one kinetic electrical generator, disposed within said power supply housing, each said at least one kinetic electrical generator comprising:
a support structure;
a pivot element, disposed within said support structure;
an oscillating weight, disposed within said support structure, having a top portion connected to said pivot element, and a bottom portion, said oscillating weight being configured and operable to achieve oscillating motion in an angular range in response to motion of said support structure that exceeds a motion threshold, said pivot element being operable to produce a reciprocating radial motion thereof, in response to said oscillating motion of said oscillating weight;
acceleration means, disposed within said oscillating weight, for decreasing said motion threshold, and for increasing said angular range of said oscillating motion of said oscillating weight in response to said motion of said support structure;
motion conversion means, connected to said pivot element, for translating said reciprocating radial motion into a rotational motion of a first velocity;
electromechanical transducer means, connected to said motion conversion means, for generating electrical energy in response to said rotational motion applied by said motion conversion means thereto; and
electrical output means for receiving said generated electrical energy from said electromechanical transducer means;
electrical energy processing means, connected to said electrical output means and positioned within said power supply housing, for modifying said generated electrical energy into electrical output power corresponding to the at least one predetermined electrical storage parameter;
a recharging control unit, connected to said electrical energy processing means and to said at least one rechargeable power supply element, and disposed within said power supply housing, operable to recharge said at least one rechargeable power supply element with said electrical output power; and
at least one power supply output interface, connected to at least one rechargeable power supply element, and positioned at least partially outside said power supply housing, operable to:
connect to the power supply input interface of the device,
modify said electrical output power to correspond to the at least one predefined electrical input parameter; and
deliver said modified electrical power to the device power supply input interface.

17. The self-recharging power supply of claim 16, further comprising a recharge interface, connected to said recharging unit and positioned at least partially outside said power supply housing, operable to receive additional electrical output power for recharging said at least one rechargeable power supply element, from an external source of electrical energy.

18. The self-recharging power supply of claim 16, wherein the power supply is configured as a battery, and wherein said at least one rechargeable power supply element is one of: at least one rechargeable battery, and at least one capacitor.

19. A portable self-recharging power supply charger, for use with at least one device each having a rechargeable power supply having a recharge input interface, capable of recharging when electrical power corresponding to a particular electrical recharge parameter is delivered to the recharge input interface, comprising:
a charger housing;
at least one rechargeable power supply element disposed within said charger housing operable to store electrical power, in a power storage amount up to a maximum capacity, having at least one predefined electrical storage parameter;
at least one kinetic electrical generator, disposed within said charger housing, each said at least one kinetic electrical generator comprising:
a support structure;
a pivot element, disposed within said support structure;
an oscillating weight, disposed within said support structure, having a top portion connected to said pivot element, and a bottom portion, said oscillating weight being configured and operable to achieve oscillating motion in an angular range in response to motion of said support structure that exceeds a motion threshold, said pivot element being operable to produce a reciprocating radial motion thereof, in response to said oscillating motion of said oscillating weight;
acceleration means, disposed within said oscillating weight, for decreasing said motion threshold, and for increasing said angular range of said oscillating motion of said oscillating weight in response to said motion of said support structure;
motion conversion means, connected to said pivot element, for translating said reciprocating radial motion into a rotational motion of a first velocity;
electromechanical transducer means, connected to said motion conversion means, for generating electrical energy in response to said rotational motion applied by said motion conversion means thereto; and
electrical output means for receiving said generated electrical energy from said electromechanical transducer means;
electrical energy processing means, connected to said electrical output means and positioned within said charger housing, for modifying said generated electrical energy into electrical output power corresponding to the at least one predetermined electrical storage parameter;
a recharging control unit, connected to said electrical energy processing means and to said at least one rechargeable power supply element, and disposed within said charger housing, operable to recharge said at least one rechargeable power supply element with said electrical output power; and
a power supply output interface, connected to at least one rechargeable power supply element, and to said recharging control unit, and positioned at least partially outside said charger housing, operable to:
connect to the recharge input interface of the device,
modify said electrical output power to correspond to the at least one predefined electrical recharge parameter; and
deliver said modified electrical power to the device power recharge input interface.

20. The self-recharging power supply charger of claim 19, further comprising a flexible elongated connector having a first end connected to said power supply output interface, and a second end configured for releasable connection to the recharge input interface of the device.

21. The self-recharging power supply charger of claim 19, further comprising control means, connected to said a power supply output interface, for selectively modifying said electrical output power to correspond to a different predefined electrical recharge parameter, selected from a predefined plurality of electrical recharge parameters, each corresponding to a particular plural device selected from a plurality of different devices, to therefore enable selective recharging of a variety of rechargeable devices.

22. The self-recharging power supply charger of claim 21, further comprising a control interface connected to said control means, operable, in response to manipulation by a user, to cause said control means to selectively modify said electrical output power to correspond to a desired predefined electrical recharge parameter for a specific desired rechargeable device.

23. The self-recharging power supply charger of claim 19, further comprising an indicator, connected to at least one of: said at least one rechargeable power supply element, and said recharging control unit, operable to communicate to a user, a current electrical energy storage amount in said at least one rechargeable power supply element.

24. The self-recharging power supply charger of claim 23, further comprising activation means, connected to said indicator, for selectively activating said indicator.

25. The self-recharging power supply charger of claim 21, wherein each said plural device comprises a unique input interface, further comprising a plurality of interface adapters each having a first end configured for releasable connection to said power supply output interface, and a second end configured for releasable connection to one of said unique input interfaces.

26. The self-recharging power supply charger of claim 25, further comprising a flexible elongated connector having a third end connected to said power supply output interface, and a fourth end configured for releasable connection to said first end of each plural interface adapter.

27. The self-recharging power supply charger of claim 19, further comprising:
a housing having a first section shaped, sized, and configured to receive and store a particular device of the at least one devices, and a second section shaped, sized, and configured to store said charge housing; and
connection means for releasably connecting said power supply output interface to the recharge input interface to recharge the particular device when the device is placed into said first section of said housing.

28. The self-recharging power supply charger of claim 19, further comprising:
a housing having a main section shaped, sized, and configured to receive and store a particular device of the at least one devices, and a plurality of accessory sections each shaped, sized, and configured to releasably store said charge housing;
connection means for releasably connecting said power supply output interface to the recharge input interface to recharge the particular device when the device is placed into said first section of said housing and when said charge housing is placed into one of said plural accessory sections.

29. A method for providing electrical power to a device of predetermined functionality having a housing and at least one functional component, disposed therein, that implements the predetermined functionality, the at least one functional component selectively requiring electrical power in response to operation of the device, the power supply being disposed within the housing, comprising the steps of:
(a) providing at least one kinetic electrical generator, disposed within the housing
(b) generating, at least one kinetic electrical generator, electrical energy in response to motion of the housing that exceeds a predefined motion threshold;
(c) converting said electrical energy into electrical output power, said electrical output power corresponding to at least a first portion of the required electrical power; and
(d) delivering said electrical output power from said at least one kinetic electrical generator, to the at least one functional component during the device operation.

30. The method of claim 29, further comprising the steps of:
(e) providing a rechargeable electrical power storage unit;
(f) instead of step (d) delivering said electrical output power to said rechargeable electrical power storage unit to store said electrical output power therein.
